(19) United States
(12) Patent Application Publication
(10) Pub. No.: US 2026/0047443 A1
(43) Pub. Date: Feb. 12, 2026

(54) PACKAGED MODULE WITH LOW MODULUS COMPOSITE MAGNETIC MOLDING MATERIAL

(71) Applicant: Monolithic Power Systems, Inc., Kirkland, WA (US)

(72) Inventors: Zhijian Sun, Campbell, CA (US); Kwang-Soo Kim, Sunnyvale, CA (US); Jian Jiang, Saratoga, CA (US)

(21) Appl. No.: 19/281,425

(22) Filed: Jul. 25, 2025

Related U.S. Application Data
(63) Continuation-in-part of application No. 19/054,748, filed on Feb. 14, 2025.
(60) Provisional application No. 63/681,799, filed on Aug. 10, 2024.

(51) Int. Cl. H01L 23/64; H01F 1/147; H01F 27/02; H01F 27/28; H01F 27/42; H01L 23/00; H01L 23/29; H01L 23/498; H01L 25/065; H01L 25/07; H01L 25/16

(52) U.S. Cl. CPC H01L 23/645; H01F 1/14766; H01F 27/022; H01F 27/027; H01F 27/2828; H01F 27/2852; H01F 27/425; H01L 23/295; H01L 23/49816; H01L 23/49827; H01L 23/49844; H01L 24/16; H01L 24/32; H01L 24/73; H01L 25/0655; H01L 25/072; H01L 25/165; H01L 2224/16227; H01L 2224/16238; H01L 2224/32227; H01L 2224/32238; H01L 2224/73204; H01L 2924/1015; H01L 2924/1206; H01L 2924/14252

(57) ABSTRACT

A packaged module includes an electrically conductive coil and a composite magnetic molding material covering the electrically conductive coil. The composite magnetic molding material includes a magnetic filler including coated magnetic particles (MB) dispersed in a composite non-magnetic material (MA). The composite magnetic molding material further includes a modulus reducing filler (MC) including modulus reducing particles or rubber particles or including functional groups having —OH or —COOH.

### CROSS-REFERENCE TO RELATED APPLICATION(S)

The present application claims the benefit and priority as a continuation in part application to U.S. patent application Ser. No. 19/054,748 filed on Feb. 14, 2025, which claims benefit and priority of U.S. Provisional Patent Application Ser. No. 63/681,799 filed on Aug. 10, 2024, and hereby incorporated fully by reference into the present application.

### TECHNICAL FIELD

This disclosure relates generally to electrical devices and associated materials and methods, and more particularly but not exclusively relates to composite magnetic material, magnetic molding material, and associated devices and methods.

### BACKGROUND

Power converters or power regulators are widely used in various electronic and/or electric applications. A power converter or a power regulator generally includes at least one power switch (such as a semiconductive switch device or a semiconductor transistor device). In operation, the power converter or power regulator provides regulated power (e.g., regulated voltage and/or current) to a load through controlling an operation status of the at least one power switch. An inductive energy storage device such as an inductor or a transformer generally co-works with the at least one power switch for power conversion. For instance, a typical switch-mode power converter as known in the art controls a power switch to perform ON and OFF switching to convert an input power to an output power for supplying a load. For example, the switch-mode power converter transfers energy from the input power to the inductive energy storage device (e.g., a current would flow through the inductive energy storage device and the current may gradually increase) when the power switch is switched ON. When the power switch is switched OFF, energy would release from the inductive energy storage device to the load (e.g., the current flowing through the inductive energy storage device may gradually decrease).

With the integration density for electric/electronic apparatus continuously desired to be increasing, power supply devices or power management devices such as power converters or power regulators with higher power handling capability yet smaller size are required. That is, high-power density power supply devices or power management devices become a trend, which renders reducing dimensions of components of these devices becomes one of the design or research challenges.

### BRIEF DESCRIPTION OF DRAWINGS

The following detailed description of various embodiments of the present invention can best be understood when read in conjunction with the following drawings, in which the features are not necessarily drawn to scale but rather are drawn as to best illustrate the pertinent features.

FIG. 1 illustrates a block diagram of a power management apparatus 100 in accordance with an embodiment of the present invention.

FIG. 2A illustratively shows a top plan view of a packaged module 10 for power conversion in accordance with an embodiment of the present invention.

FIG. 2B illustratively shows a cross-sectional view of the packaged module 10 taken along the sectional line A-A′ in top plan view of FIG. 2A in accordance with an embodiment of the present invention.

FIG. 2C shows a top plan view of a packaged module 20 for power conversion in accordance with an embodiment of the present invention.

FIG. 2D illustratively shows a cross-sectional view of the packaged module 20 taken along the sectional line A-A′ in top plan view of FIG. 2C in accordance with an embodiment of the present invention.

FIG. 2E and FIG. 2F illustratively show cross-sectional views of the packaged module 20 taken along the sectional line A-A′ in top plan view of FIG. 2C in accordance with alternative embodiments of the present invention.

FIG. 2G illustrates a waveform diagram illustrating a curve of the relative magnetic permeability μr of the MMC 14 versus a switching frequency in accordance with an embodiment of the present disclosure.

FIG. 3A illustratively shows a top plan view of a packaged module 30 for power conversion in accordance with an embodiment of the present invention.

FIG. 3B illustratively shows a cross-sectional view of the packaged module 30 taken along the sectional line A-A′ in top plan view of FIG. 3A in accordance with an embodiment of the present invention.

FIG. 3C shows a top plan view of a packaged module 40 for power conversion in accordance with an embodiment of the present invention.

FIG. 3D illustratively shows a cross-sectional view of the packaged module 40 taken along the sectional line A-A′ in top plan view of FIG. 3C in accordance with an embodiment of the present invention.

FIG. 4A illustratively shows a top plan view of a packaged module 50 for power conversion in accordance with an embodiment of the present invention.

FIG. 4B illustratively shows a cross-sectional view of the packaged module 50 taken along the sectional line A-A′ in top plan view of FIG. 4A in accordance with an embodiment of the present invention.

FIG. 4C illustratively shows a cross-sectional view of the packaged module 50 taken along the sectional line A-A′ in top plan view of FIG. 4A in accordance with an alternative embodiment of the present invention.

FIG. 5A illustratively shows a top plan view of a packaged module 60 for power conversion in accordance with an embodiment of the present invention.

FIG. 5B illustratively shows a cross-sectional view of the packaged module 60 taken along the sectional line A-A′ in top plan view of FIG. 5A in accordance with an embodiment of the present invention.

FIG. 5C illustratively shows a cross-sectional view of the packaged module 60 taken along the sectional line A-A′ in top plan view of FIG. 5A in accordance with an alternative embodiment of the present invention.

FIG. 6A illustratively shows a perspective top plan view of a packaged module 70 for power conversion in accordance with an embodiment of the present invention.

FIG. 6B illustratively shows a cross-sectional view of the packaged module 70 taken along the sectional line A-A′ in the perspective top plan view of FIG. 6A in accordance with an embodiment of the present invention.

FIG. 7A illustratively shows a perspective top plan view of a packaged module 80 for power conversion in accordance with an embodiment of the present invention.

FIG. 7B illustratively shows a cross-sectional view of the packaged module 80 taken along the sectional line A-A′ in the perspective top plan view of FIG. 7A in accordance with an embodiment of the present invention.

FIG. 7C illustratively shows a perspective 3-dimensional view of a packaged module 81 for power conversion in accordance with an alternative embodiment of the present invention.

FIG. 7D illustratively shows a perspective side view of the packaged module 81 when inspected from the right-hand side (as indicated by the arrow 802) in the perspective 3-dimensional view of FIG. 7C in accordance with an embodiment of the present invention.

FIG. 7E illustratively shows a perspective top plan view of the packaged module 81 for power conversion in accordance with an embodiment of the present invention.

FIG. 7F illustratively shows a perspective 3-dimensional view of a packaged module 82 for power conversion in accordance with an alternative embodiment of the present invention.

FIG. 7G illustratively shows an enlarged top plan view of the electrically conductive coil 13 in accordance with an embodiment.

FIG. 7H and FIG. 7I respectively illustratively shows enlarged perspective side views of the electrically conductive coil 13 in accordance with an embodiment.

FIG. 7J and FIG. 7K respectively illustratively shows enlarged perspective side views of the electrically conductive coil 13 in accordance with an alternative embodiment.

FIG. 7L illustratively shows a perspective top plan view of the packaged module 82 for power conversion in accordance with an embodiment of the present invention.

FIG. 8A illustratively shows a perspective top plan view of a packaged module 90 for power conversion in accordance with an embodiment of the present invention.

FIG. 8B illustratively shows a cross-sectional view of the packaged module 90 taken along the sectional line A-A′ in the perspective top plan view of FIG. 8A in accordance with an embodiment of the present invention.

FIG. 8C illustratively shows a perspective top plan view of a packaged module 91 for power conversion in accordance with an embodiment of the present invention.

FIG. 8D illustratively shows a cross-sectional view of the packaged module 91 taken along the sectional line A-A′ in the perspective top plan view of FIG. 8C in accordance with an embodiment of the present invention.

FIG. 8E illustratively shows a perspective top plan view of a packaged module 92 for power conversion in accordance with an embodiment of the present invention.

FIG. 8F illustratively shows a cross-sectional view of the packaged module 92 taken along the sectional line A-A′ in the perspective top plan view of FIG. 8E in accordance with an embodiment of the present invention.

FIG. 8G illustratively shows a perspective top plan view of a packaged module 94 for power conversion in accordance with an embodiment of the present invention.

FIG. 8H illustratively shows a cross-sectional view of the packaged module 94 taken along the sectional line A-A′ in the perspective top plan view of FIG. 8G in accordance with an embodiment of the present invention.

FIG. 8I illustratively shows a perspective top plan view of a packaged module 96 for power conversion in accordance with an embodiment of the present invention.

FIG. 8J illustratively shows a cross-sectional view of the packaged module 96 taken along the sectional line A-A′ in the perspective top plan view of FIG. 8I in accordance with an embodiment of the present invention.

FIG. 8K illustrates a simulation waveform diagram illustrating a curve of the power conversion efficiency of a packaged module versus an operating current (e.g., a load current provided at the output terminal of the packaged module) of the packaged module in accordance with an embodiment of the present invention.

FIG. 9 illustrates a process flow chart showing a method 900 for manufacturing a packaged module for power conversion in accordance with an embodiment of the present invention.

FIG. 10 illustrates a process flow chart showing a method 1000 for manufacturing a packaged module for power conversion in accordance with an alternative embodiment of the present invention.

FIG. 11 illustrates a waveform diagram illustrating a curve of a relative magnetic permeability ur of some samples of a composite magnetic material versus a switching frequency in accordance with some embodiments of the present disclosure.

FIG. 12 which illustratively shows a portion of the composite magnetic material including island structures within a composite non-magnetic material (MA) in accordance with some embodiments of the present disclosure.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the term “coupled,” as used herein, is defined as directly or indirectly connected in an electrical or non-electrical manner. When an element is described as “connected” or “coupled” to another element, it can be directly connected or coupled to the other element, or there could exist one or more intermediate elements. In contrast, when an element is referred to as “directly connected” or “directly coupled” to another element, there is no intermediate element. In addition, “electrically connected” or “electrically coupled” means the concept including a physical connection and a physical disconnection, which enables an electrical coupling between elements. It can be understood that when an element is referred to with “first” or “second” or the like, the element is not limited thereby. The terms “first” or “second” or the like may be used only for a purpose of distinguishing the element from the other elements being modified by these terms and may not limit the sequence or importance of the elements being modified unless the context clearly dictates otherwise. The terms “a,” “an,” and “the” include plural reference, and the term “in” includes “in” and “on” unless the context clearly dictates otherwise. The phrase “in one embodiment,” as used herein does not necessarily refer to the same embodiment, although it may. The term “or” is an inclusive “or” operator, and is equivalent to the term “and/or” herein, unless the context clearly dictates otherwise. The term “and/or” may include individual or any combination of the elements being referenced in conjunction with the term. The term “based on” is not exclusive and allows for being based on additional factors not described, unless the context clearly dictates otherwise. The term “circuit” means at least either a single component or a multiplicity of components, either active and/or passive, that are coupled together to provide a desired function. The term “signal” means at least one current, voltage, charge, temperature, data, or other signal. Those skilled in the art should understand that the meanings of the terms identified above do not necessarily limit the terms, but merely provide illustrative examples for the terms.

The terms “comprise”, “include”, “have” and any variations thereof, are intended to cover non-exclusive inclusions, such that a process, method, article, or apparatus that comprises a list of elements is not necessarily limited to those elements, but may include other elements not expressly listed or inherent to such process, method, article, or apparatus.

The terms “left,” right,” “in,” “out,” “front,” “back,” “up,” “down, “top,” “atop”, “bottom,” “over,” “under,” “above,” “below”, “lower”, “upper” and the like in the description and the claims, if any, are used for descriptive purposes and for convenience of explanation and not necessarily for describing permanent relative positions. It is to be understood that the terms so used are interchangeable under appropriate circumstances such that embodiments of the invention described herein are, for example, capable of operation in other orientations than those illustrated or otherwise described herein, and the claims are not particularly limited by the positions or directions as described with those terms.

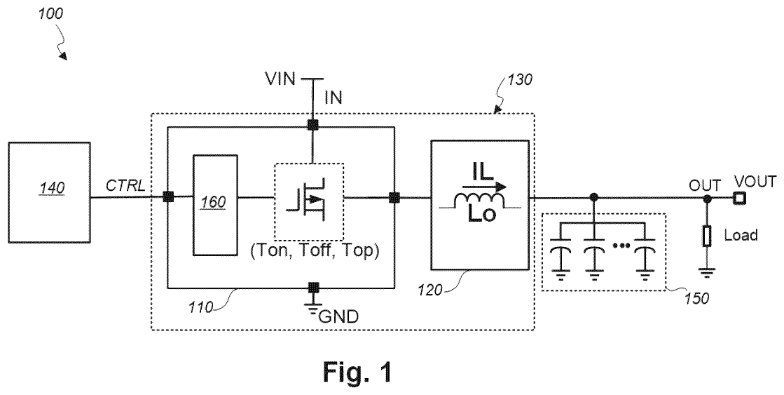

For convenience of explanation, the present disclosure may take a specific semiconductor device as an example for the explanation, but this is not intended to be limiting and persons of skill in the art will understand that the structure and principles taught herein also apply to other semiconductor devices. Various embodiments are discussed below with reference to FIG. 1 to FIG. 10. The detailed description given herein with respect to the figures is for explanatory purposes only and should not be construed as limiting.

FIG. 1 illustrates a block diagram of a power management apparatus 100 in accordance with an embodiment of the present invention. The power management apparatus 100 may be adapted to be used for sourcing power from a power source to a load. The power management apparatus 100 may have an input terminal IN adapted to receive an input power from the power source and an output terminal OUT adapted to provide an output power. The power source may comprise a power supply such as a battery/battery pack or other circuit for providing power to another circuit. In the example of FIG. 1, the power source provides power in the form of an input voltage VIN, which may be a DC voltage. However, this is not to be limiting, power source that can provide an input power to the power management apparatus 100 in other forms is applicable.

In an embodiment, the power management apparatus 100 may include a power switching unit 110. The power switching unit 110 may be adapted to regulate energy or power transmitted from the input terminal IN to the output terminal OUT (or to the load) in response to control signal(s) (e.g. a control signal CTRL illustrated in the example of FIG. 1). In an embodiment, the power switching unit 110 may include at least one power switch such as a power transistor device that may be controllable to implement ON and OFF switching. In an embodiment, the power switching unit 110 may further include a driver 160 to drive the at least one power switch in the power switching unit 110.

In accordance with an exemplary embodiment, the power switching unit 110 may be adapted to be configurable for controlling a switching between an energy storage and an energy release in an inductive energy storage device 120 based on the control signal(s) (such as the control signal CTRL illustrated in FIG. 1), thereby converting the input power (e.g., in the form of an input volage VIN and/or li in FIG. 1) to the output power (e.g., in the form of an output voltage VOUT and/or lo in FIG. 1). During the energy storage, energy may be transferred to and stored in the inductive energy storage device 120 (e.g., a current would flow through the inductive energy storage device 120 and the current may gradually increase). During the energy release, energy may be released and transferred out from the inductive energy storage device 120 (e.g., the current flowing through the inductive energy storage device 120 may gradually decrease. Generally, a period during which the power switching unit 110 may be configured to couple the inductive energy storage device 120 such that energy may be transferred from the input terminal IN to the inductive energy storage device 120 for the energy storage may be referred to as an on time Ton (which can also be considered as an on time of the power switching unit 110 or may also be referred to as an on time of the power management apparatus 100), and a period during which the power switching unit 110 may be configured to couple the inductive energy storage device 120 such that energy may be transferred from the inductive energy storage device 120 to the output terminal OUT for energy release may be referred to as an off time Toff (which can also be considered as an off time of the power switching unit 110 or may also be referred to as an off time of the power management apparatus 100). The sum of the on time Ton and the off time Toff experienced every time a switching between the energy storage and the energy release in the inductive energy storage device 120 is completed may be referred to as an operating cycle or switching cycle Top of the power management apparatus 100, and a ratio of the on time Ton to the sum of the on time Ton and the off time Toff in each operating cycle Top may be referred to as an on-duty ratio of the power switching unit 110 or a duty ratio of the power management apparatus 100. The control signal(s) such as the control signal CTRL illustrated in FIG. 1 may be adapted to control the power switching unit 110 to implement switching between the energy storage and the energy release in the inductive energy storage device 120 and may be adapted to regulate the on time Ton and/or the off time Toff or the duty ratio or the switching cycle Top (or a switching frequency Fop=1/Top). In this fashion, the energy or power transmitted to the output terminal OUT in each switching cycle may be regulated. For instance, the output power in the form of the output voltage VOUT and/or the output current lo may be regulated.

In accordance with an exemplary embodiment, the power switching unit 110 may be configured to co-work with the inductive energy storage device 120 to implement a power conversion topology 130. The power conversion topology 130 may include any isolated or non-isolated synchronous or non-synchronous power conversion topology including but not limited to a DC to DC power conversion topology or an AC to DC power conversion topology or a DC to AC power conversion topology, etc. In an example, the power conversion topology 130 may include a synchronous non-isolated DC to DC power conversion topology, for instance, a DC to DC buck power conversion topology, or a DC to DC boost power conversion topology, or a DC to DC buck-boost power conversion topology.

In an embodiment, the power management apparatus 100 may further include a control unit 140 to provide the control signal(s) for controlling the power switching unit 110. In an embodiment, the control unit 140 may be adapted to provide the control signal(s) to the power switching unit 110 based on information indicative of the input voltage VIN, and/or information indicative of the output voltage VOUT, and/or information indicative of the output current lo etc.

In an embodiment, a capacitive energy storage unit 150 may be coupled to the output terminal OUT. The capacitive energy storage unit 150 may include one or more capacitors for example and may be operated as an output filter to smooth the output voltage VOUT at the output terminal OUT. One of ordinary skill in the art would understand that the power management apparatus 100 may include other active components and/or passive components that may not be addressed in detail here.

Conventionally, the passive components, for instance especially the inductive energy storage device 120, are provided as discrete components which take a large physical volume or space to be mounted on a substrate or circuit board of an application system where the power management apparatus 100 may be used in/for. For example, a conventional inductor is provided as an individually packaged discrete component and is formed by providing a magnetic core (e.g., a ferrite core) with surrounding electrically conductive windings around the magnetic core on a substrate (the substrate of the discrete inductor package) and molding the magnetic core and associated windings within a conventional molding compound (such as plastics, epoxy compound etc.) so that a packaged discrete inductor/magnetic device is fabricated. The packaged discrete inductor/magnetic device has electrical leads protruding from its substrate so that the packaged discrete inductor/magnetic device can be mounted to another substrate or circuit board of a larger system such as a power converter. Examples of such kind of packaged discrete inductor/magnetic device are disclosed in U.S. Pat. No. 5,787,569, entitled “Encapsulated Package for Power Magnetic Devices and Method of Manufacture Therefor,” to Lotfi, et al. (“Lotfi′), issued on Aug. 4, 1998, and U.S. Pat. No. 7,462,317, entitled “Method of manufacturing an encapsulated package for a magnetic device,” to Lotfi, et al. (“Lotfi′), issued on Dec. 9, 2008.

In addition, such kind of individually packaged discrete inductor/magnetic device when being used in a power management apparatus (such as a power converter) having other components (such as power switching device, capacitors, resistors etc.) that may need to be packaged together as a power converter module which is conventionally encapsulated with a conventional molding compound (such as plastics, epoxy compound etc.) may greatly limit the minimum physical dimension of the power converter module.

In order to increase an integration density and/or a power density of the power management apparatus 100 and/or the application system including the same, in an embodiment, the power switching unit 110 and the inductive energy storage device 120 may be integrated in a packaged module that may be encapsulated by a magnetic molding compound (“MMC”) instead of a conventional molding compound (such as plastics, epoxy compound etc.). The packaged module in accordance with various embodiments of the present disclosure may have a smaller size or physical dimension and may take a smaller space to be mounted on the circuit board in comparison to the conventional way of using an individually packaged discrete inductor/magnetic device to implement the inductive energy storage device 120 and/or in comparison with the conventional power converter module having the individually packaged discrete inductor/magnetic device and other components encapsulated with a conventional molding compound. In an embodiment, the power switching unit 110 may be implemented and fabricated in an integrated circuit (“IC”) die. In an embodiment, the control unit 140 may be fabricated and/or integrated on the same IC die as the power switching unit 110 is integrated on. In an alternative embodiment, the control unit 140 may be fabricated and/or integrated on a separate IC die from that of the power switching unit 110. In still an alternative embodiment, the control unit 140 may be provided from other circuitry of the application system that includes the power management apparatus 100. For instance, a micro controller in the application system may be configured to implement the functionality of the control unit 140.

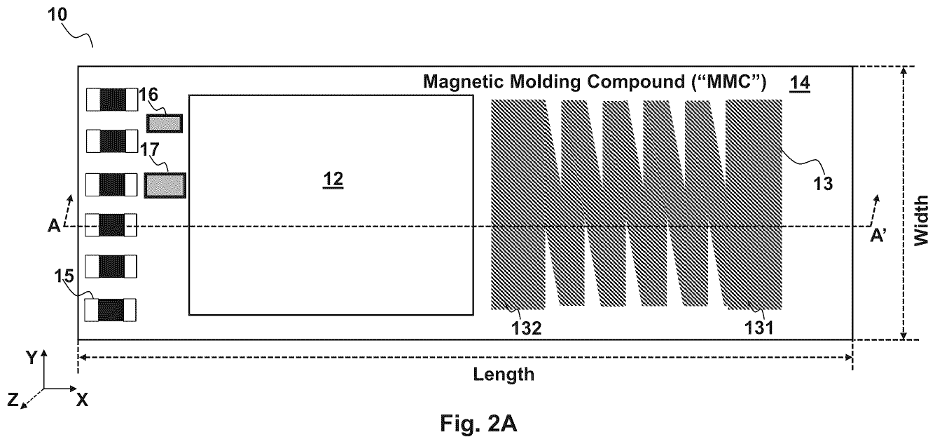

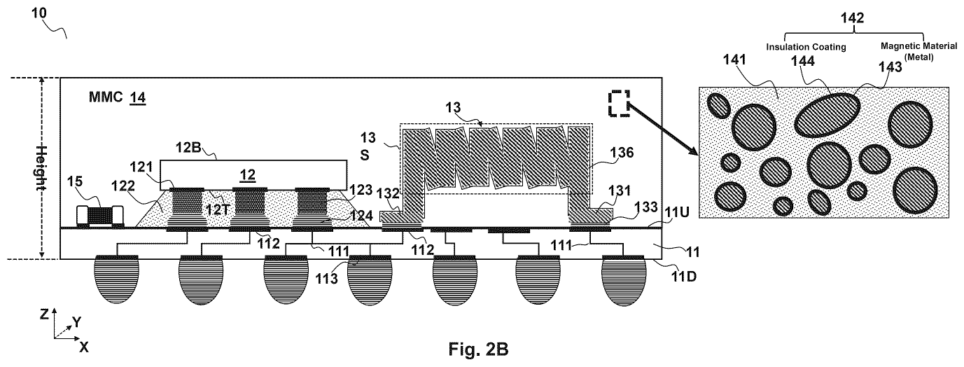

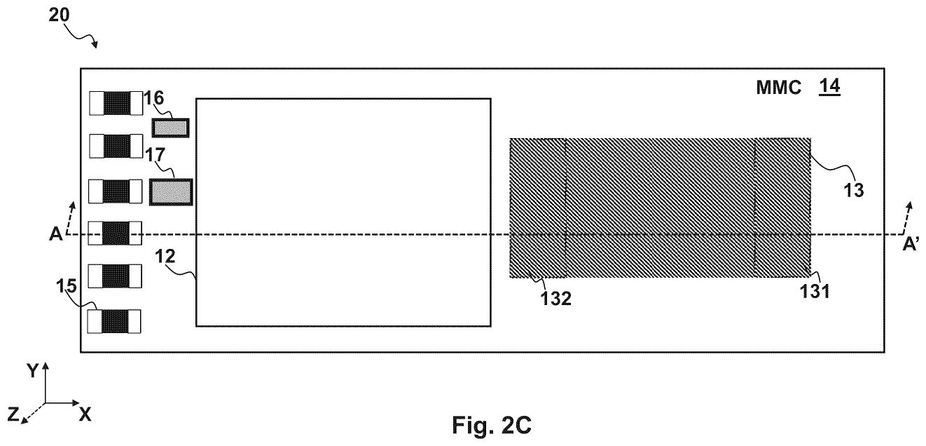

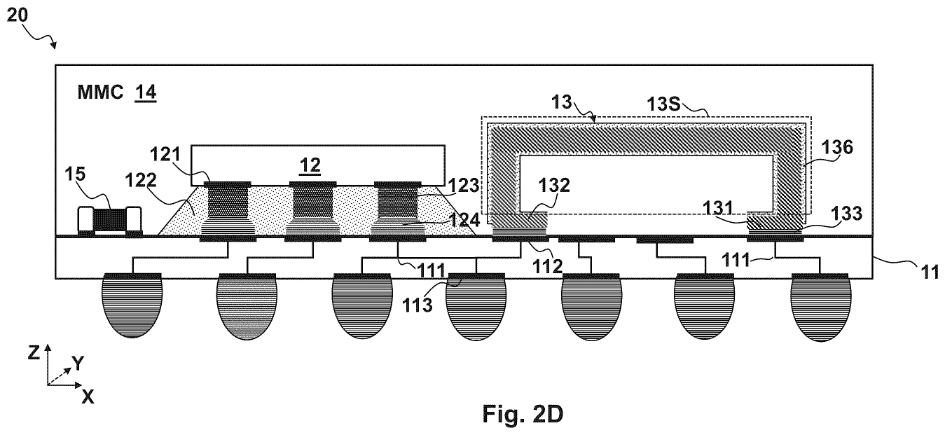

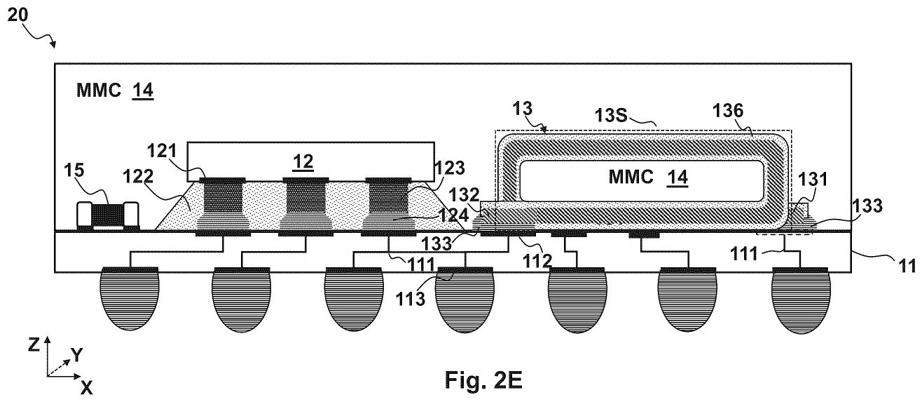

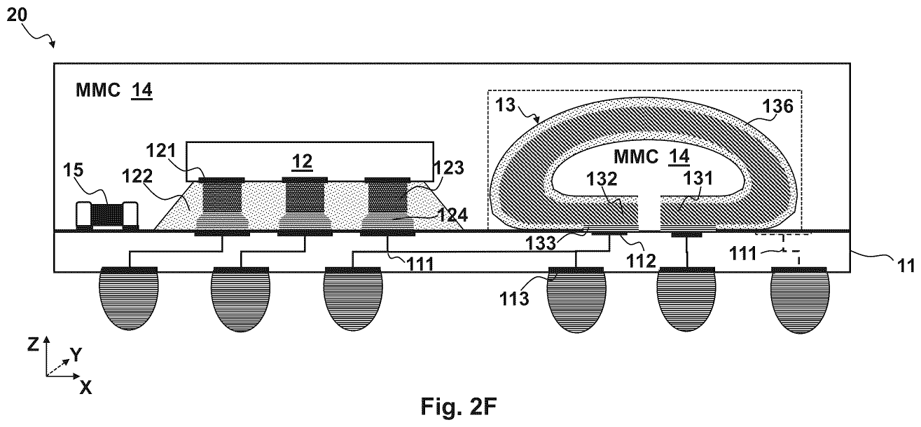

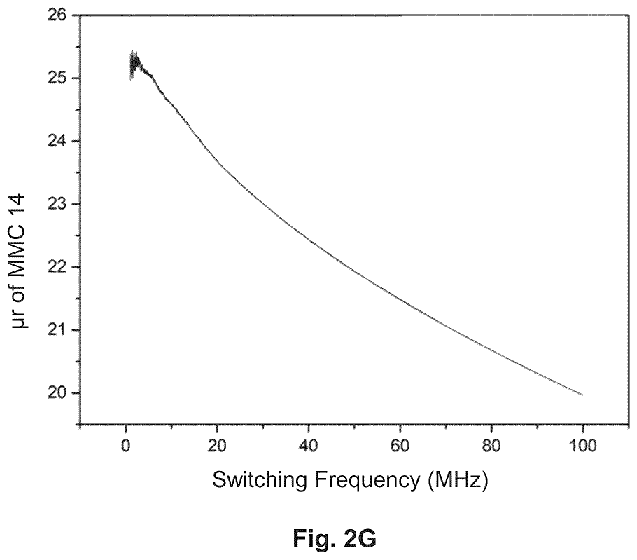

FIG. 2A illustratively shows a top plan view of a packaged module 10 in accordance with an embodiment of the present invention. FIG. 2B illustratively shows a cross-sectional view of the packaged module 10 taken along the sectional line A-A′ in top plan view of FIG. 2A in accordance with an embodiment of the present invention. The top plan view in FIG. 2A and the cross-sectional view in FIG. 2B may be considered as illustrated out in a 3-dimensional coordinate system having the x axis, y axis and z axis perpendicular to one another. It may be understood that the illustrative cross-sectional view may be considered as inspected from/taken from a cutting plane parallel to the x-z plane defined by the x and z axis. Throughout this disclosure, lateral may refer to a direction parallel to the x axis while vertical may refer to a direction parallel to the z axis in the cross-sectional views. Length may refer to a size measured in the direction parallel to the x axis, width may refer to a size measured in the direction parallel to the y axis, and height, depth and/or thickness may refer to a size measured in the direction parallel to the z axis. Alternatively speaking, the x axis direction refers to a direction along a length of the packaged module 10, the y axis direction refers to a direction along a width of the packaged module 10, and the z axis direction refers to a direction along a height of the packaged module 10. The packaged module 10 may be described and understood with reference to FIG. 2A and FIG. 2B collectively.

The packaged module 10 may include a substrate 11, a power switching unit 12 and an electrically conductive coil 13. An electrically conductive coil 13 may be mounted on the substrate 11. A power switching unit 12 may further be disposed in the package module 10. In an embodiment, the power switching unit 12 and the electrically conductive coil 13 may be mounted on the substrate 11 such that the power switching unit 12 and the electrically conductive coil 13 may co-work or cooperate with each other. For instance, the power switching unit 12 may be coupled to the electrically conductive coil 13. Other circuit components such as capacitive energy storage devices (e.g., capacitors) 15, resistive devices (e.g., resistors) 16 and/or other devices 17 etc. may also be mounted to the substrate 11. A magnetic molding compound (“MMC”) 14 may be used to encapsulate the packaged module 10, for example to encase or cover or wrap the components (including but not limited to the power switching unit 12 and/or the electrically conductive coil 13) mounted to the substrate 11. In an embodiment, the packaged module 10 for power conversion may be configured to implement the power management apparatus 100 or at least the power conversion topology 130 of the power management apparatus 100.

The power switching unit 12 may be an implementation of the power switching unit 110 as described above in the examples with reference to FIG. 1. For instance, the power switching unit 12 may be a semiconductor die or an integrated circuit die having integrated circuits to perform the functions of the power switching unit 110 fabricated therein. Referring to the example shown in FIG. 2B, the power switching unit 12 may have conductive pads 121 formed at a top surface (e.g., also referred to as an active surface) 12T of the power switching unit 12 to electrically lead out terminals of integrated circuits that are formed inside the power switching unit 12 so that the power switching unit 12 may be directly attached to the substrate 11, for instance attached onto a first surface 11U of the substrate 11 with the top surface 12T flipped downward facing the first surface 11U of the substrate 11. In an embodiment, each of the conductive pads 121 may be connected with a conductive pillar/bump 123 that may be attached to the substrate 11 and connected to a corresponding pad (e.g., see 112) formed on the first surface 11U via a conductive die attaching material (e.g., solder paste) 124. The top surface (e.g., the active surface) 12T of the power switching unit 12 may refer to the surface where the conductive pads 121 and/or the conductive pillars 123 are formed/attached thereon. A back surface 12B of the power switching unit 12 is opposite to the top surface 12T. The power switching unit 12 may thus be referred to as a flip chip semiconductor die in an example with the top surface 12T adapted to be attached to the substrate 11. An underfill material 122 may fill cavities among the conductive pillars 123 and between the top surface 12T of the power switching unit 12 and the first surface 11U of the substrate 11. The underfill material 122 electrically isolates the conductive pads 121 and/or the conductive pillars 123 from the MMC 14.

The electrically conductive coil 13 may be formed of electrically conductive materials such as metal, metal composition or alloy etc. For instance, in an embodiment, the electrically conductive coil 13 may be of copper, aluminum, nickel etc., or alloys thereof. The electrically conductive coil 13 may be formed to have various shapes such that the electrically conductive coil 13 may be adapted to operate/function as one or more windings of an inductive energy storage device.

In an embodiment, as shown in the examples of FIG. 2A and FIG. 2B, the electrically conductive coil 13 may be of helix-like shape and may be operated as one or more multi-turn windings of an inductive energy storage device. Although there's one multi-turn winding having wiring turns wound along the x-axis direction (i.e., direction along the length of the packaged module) illustrated in the examples of FIG. 2A and FIG. 2B, it would be understood that this is just illustrative and exemplary and not intended to be limiting. It can be easily understood by those skilled in the art that when speaking of the wiring turn(s) wound along a specific direction (e.g., the x-axis direction in FIG. 2A and FIG. 2B), the wiring turn(s) are formed by winding/coiling a coil wire turn by turn surrounding or circling that specific direction, for example, with the wiring turn(s) spreading turn by turn along that specific direction. In some embodiments, the electrically conductive coil 13 may be formed as a flat-wire multi-turn winding by winding/coiling a flat coil wire. In some other embodiments, the electrically conductive coil 13 may be formed as a round-wire multi-turn winding by winding/coiling a round coil wire. In still some alternative examples, the electrically conductive coil 13 may include more windings that are formed according to practical application requirements, and each winding may have a single turn or multiple wiring turns that may not be necessarily wound along the x-axis direction. The turn(s) of each winding may be wound along other directions and do not depart from the spirit of the present disclosure.

In the examples of FIG. 2A and FIG. 2B, although it is illustrated that a substantial body (as indicated in the dashed frame 13S, substantially including the turn(s) of each winding) of the electrically conductive coil 13 is vertically spaced apart from the substrate 11, it can be understood that in other embodiments, the electrically conductive coil 13 may have a substantial body that is not vertically spaced apart from the substrate 11. For example, the electrically conductive coil 13 may have a substantial body directly disposed on the substrate 11 with a bottom side of the substantial body essentially contacting the substrate 11 in some alternative embodiments. Those skilled in the art would understand that variations cannot be exhaustively exampled and can be obtained by studying the descriptions and drawings of the present disclosure, and thus do not depart from the spirit and scope of the present disclosure.

The electrically conductive coil 13 may have coil terminals (such as a first coil terminal 131 and a second coil terminal 132 for each winding) that are integrally formed with the electrically conductive coil 13. In accordance with an embodiment, the coil terminals may be adapted to be directly attached to the substrate 11 so that the electrically conductive coil 13 can be directly mounted on the substrate 11 and the inductive energy storage device may be coupled to the substrate 11. As is apparent by its common plain meaning, the term “integrally formed” intrinsically implies that the coil terminals are implemented as integral portions of the electrically conductive coil 13 just like the substantial body 13S, without being joint by extra means of connecting for example welding, soldering etc. In perspectives of “adapted to be directly attached to the substrate 11”, the coil terminals are configured to be substantially coplanar with each other so that they can land on the first surface 11U of the substrate 11 substantially simultaneously without substantial vertical difference referencing to the first surface 11U when placing the electrically conductive coil 13 on the substrate 11. For example, the coil terminals are substantially coplanar with each other with a mismatching tolerance within a predetermined range (e.g. +5%) so that the coil terminals can be well attached to the substrate 11 by a conductive attaching material (e.g., solder paste) with good reliability. Each one of the coil terminals may be integrally connected with a wiring turn of the electrically conductive coil 13 by a bending portion of the coil wire in some embodiments depending on the predetermined direction along which the wiring turn(s) of the electrically conductive coil 13 are wound. The design of the electrically conductive coil 13 in accordance with the exemplary embodiments of the present disclosure makes it easier to be implemented for mass production, and improves a mounting yield and a mounting efficiency of mounting the electrically conductive coil 13 on to the substrate 11, with a surface mount technology (“SMT”) for example, and reduces the complexity and cost of manufacturing and production, which is long desired need to address since there are practically tough challenges for successfully and productively mounting the electrically conductive coil 13 to satisfy the requirements of massive production as can be well understood by those of ordinary skill in the art, considering that the packaged module has a very small and limited size (for example the packaged module in an embodiment has a size no greater than 2 mm*3 mm*1.5 mm for supporting an operating current up to 4A˜6A), and the electrically conductive coil 13 accordingly should have a quite small size (e.g., being small enough to be accommodated in the packaged module) and is wound with very thin coil wire (e.g., having a wire diameter no greater than 0.3 mm for round coil wire in an embodiment or a wire thickness ranging from 0.03 mm to 0.3 mm for flat coil wire in an embodiment) that is fragile and hard for picking, placing, and attaching (e.g., soldering) during the mounting process. Embodiments of the present disclosure advantageously overcome these tough challenges and the electrically conductive coil 13 is uneasy to fall during a reflow process.

The electrically conductive coil 13 may be conformally coated with a thin insulation layer 136 except for the coil terminals. At least portions (e.g., at bottom surfaces) of the coil terminals (e.g., the first terminal 131 and the second coil terminal 132 in the present examples) are free of coverage from the thin insulation layer 139. That is, the thin insulation layer 136 coating the electrically conductive coil 13 is stripped at least at portions (e.g., at bottom surfaces) of the coil terminals (e.g., the first terminal 131 and the second coil terminal 132 in the present examples) so that the coil 13 is suitable to be directly attached to the substrate 11 with the coil terminals configured to provide availability of electrical connections/couplings. For example, the coil terminals (e.g., the first terminal 131 and the second coil terminal 132 in the present examples) may be attached to corresponding pads (e.g., still see 112) on the first surface 11U of the substrate 11 for example by a conductive attaching material (e.g., solder paste) 133. Pads 112 may be formed on the first surface 11U of the substrate 11 according to practical design and connection requirements as can be understood by those of ordinary skill in the art. The thin insulation layer 136 will not be specifically illustrated out in the drawings related to rest of the examples or embodiments that would be provided in the present disclosure for concise purpose, unless when descriptions may be related to the thin insulation layer 136 which would be illustrated out for some embodiments.

The MMC 14 may provide a high relative magnetic permeability (for example 20-50) and a low core-loss density. It is known to those skilled in the art that a magnetic permeability u of a material is defined as a ratio of a magnetic induction density (i.e., a magnetic flux density) B produced within the material by a magnetizing field to a magnetic field intensity H of the a magnetizing field, that is μ=B/H, which helps to measure the material's resistance to the magnetizing field or measure the degree to which a magnetizing field can penetrate through the material. A relative magnetic permeability of a specific medium or material, normally denoted by the symbol μr, is a ratio of the magnetic permeability of the specific medium or material to the magnetic permeability of free space μ₀ (which is also known as the magnetic permeability in a classical vacuum), that is μr=μ/μ₀, where μ₀≈4π×10⁻⁷ H/m. Therefore, a relative permeability of the MMC 14 is a dimensionless quantity that is defined as a ratio of the magnetic permeability of the MMC 14 to the magnetic permeability of free space μ₀. In some embodiments, referring to FIG. 2G which illustrates a waveform diagram illustrating a curve of the relative magnetic permeability μr of the MMC 14 versus a switching frequency (e.g., of the packaged modules) in accordance with an embodiment of the present disclosure, the MMC 14 has a relative magnetic permeability essentially ranging from 20 to 25 to support the packaged modules according to various embodiments of the present invention adapted to be configured to operate with a switching frequency up to 100 MHz. In some embodiments, the MMC 14 with the relative magnetic permeability essentially ranging from 20 to 25 may support the formation of an integrated inductive energy storage device that includes the MMC14 and the electrically conductive coil 13 having an inductance of up to 2 μH.

In some embodiments, the MMC 14 extends upwards from the first surface 11U of the substrate 11 and fills any space or volume that is un-occupied by the components mounted on the substrate 11 until it covers the tallest component among the components mounted on the substrate 11. The MMC 14 in an embodiment may include coated magnetic particles 142 dispersed in a non-magnetic material 141. In one embodiment, the non-magnetic material 141 may include a mixture comprising resin (or epoxy), hardener, and catalyst etc., but with no silicon dioxide included which means that the non-magnetic material 141 is silicon dioxide free. Each one of the coated magnetic particles 142 may include a magnetic metal particle 143 and an insulation coating layer 144 enclosing or wrapping the magnetic metal particle 143. That is, each magnetic metal particle 143 is coated and encapsulated inside the insulation coating layer 144 and thus separated from the non-magnetic material 141 by the insulation coating layer 144. The insulation coating layer 144 may include a layer of polymer such as silane coupling agents. The insulation coating layer 144 may advantageously help to enhance uniformity of dispersion of the coated magnetic particles 142 within the non-magnetic material 141 and improve electrical resistivity of the MMC 14. In an embodiment, each magnetic metal particle 143 may include iron at least of 60%. In an embodiment, the coated magnetic particles 142 may have non-uniform sizes and/or may have non-uniform/non-identical (i.e., various) shapes to reduce the viscosity and improve the permeability. The MMC 14 may have a much higher thermal conductivity than that of the conventional molding compound (such as plastics, epoxy compound etc.) because the coated magnetic particles 142 with higher thermal conductivity than the conventional molding compound particles can greatly enhance the thermal conductivity of the MMC 14.

In accordance with an exemplary embodiment, the electrically conductive coil 13 and the MMC 14 may form an integrated inductive energy storage device that may be used as the inductive energy storage device 120 as described above in the examples with reference to FIG. 1. With the MMC 14 interacting with the electrically conductive coil 13, various embodiments of the present invention may eliminate the conventional molding compound (such as plastics, epoxy compound etc.) and the magnetic core of the conventional individually packaged discrete inductor/magnetic device which occupy most volume of a conventional power converter module. Therefore, in accordance with various embodiments of the present disclosure, there's no need to dispose a magnetic core (e.g., a ferrite core) in the electrically conductive coil 13 in one aspect owing to the high magnetic permeability and various other features of the MMC 14 and in another aspect owing to design of the electrically conductive coil 13, which may for example advantageously help to reduce a physical dimension of the integrated inductive energy storage device without degrading the energy storage capacity/performance of the integrated inductive energy storage device. In other words, the electrically conductive coil 13 in accordance with various embodiments of the present disclosure can be mentioned as core-less (or core-free). The integrated inductive energy storage device in accordance with various embodiments of the present disclosure that includes the MMC 14 interacting with the electrically conductive coil 13 can be mentioned as core-less (or core-free). In another aspect, this may provide various flexibility to place the electrically conductive coil 13 when integrating the same in the packaged module. For instance, in the examples of FIG. 2A and FIG. 2B, the electrically conductive coil 13 and the corresponding switching unit 12 are illustrated as placed side-by-side on the substrate 11 and laterally spaced apart from each other. The packaged module 10 has a reduced size compared to the conventional power converter module at least owing to using the integrated inductive energy storage device which replaces the conventional individually packaged discrete inductor/magnetic device. In still another aspect, the MMC 14 may advantageously enhance an inductance and lower a direct current resistance (“DCR”) of the inductive energy storage device. In yet another aspect, since the MMC 14 replaces the conventional molding compound to encapsulate the packaged module 10, which means more space is saved out for the inductive energy storage device to occupy in the packaged module 10 (that is, the inductive energy storage device may occupy a greater percentage of the total volume of the packaged module 10), more intricate structures to reduce power loss resulted from the inductive energy storage device may be available, thereby improving a power conversion efficiency of the packaged module 10 for power conversion which for example may have the power management apparatus 100 packaged therein. In still yet another aspect, since the MMC 14 may have much higher thermal conductivity than that of the conventional molding compound (such as plastics, epoxy compound etc.), thermal spreading or heat dissipation from the components (including but not limited to the power switching unit 12 and the electrically conductive coil 13) packaged inside the packaged module 10 may be enhanced, and thus the packaged module 10 encapsulated with the MMC 14 may have a better thermal dissipation performance.

One of ordinary skill in the art would understand that although in the examples of FIG. 2A and FIG. 2B, one power switching unit 12 and one corresponding electrically conductive coil 13 are illustrated out, there may be more power switching units and corresponding electrically conductive coils 13 formed in the packaged module 10.

The substrate 11 may include a plurality of electrically conductive wiring structures 111. Some of the electrically conductive wiring structures 111 may be adapted to provide interconnection or electrical coupling between the power switching unit 12 and the corresponding conductive coil 13 so that in operation the power switching unit 12 may control a switching of an energy storage and an energy release in the inductive energy storage device comprising the corresponding conductive coil 13 and the MMC 14. During the energy storage, energy may be transferred to and stored in the inductive energy storage device (e.g., a current would flow through the inductive energy storage device and the current may gradually increase). During the energy release, energy may be released and transferred out from the inductive energy storage device (e.g., the current flowing through the inductive energy storage device may gradually decrease). Some others of the electrically conductive wiring structures 111 may be adapted to provide electrical couplings and/or electrical connections so that electrical couplings and/or electrical connections and/or signal communications among the components (e.g., power switching units 12, conductive coils 13, capacitive devices 15, resistive devices 16 or other components 17 etc.) inside the packaged module 10 and/or between the components inside the packaged module 10 and other external circuits or elements outside the packaged module 10 may be realized. The substrate 11 may have a single substrate layer or may alternatively have multiple substrate layers. A second surface 11D of the substrate 11 that is opposite to the first surface 11U of the substrate 11 may be configured as a pin side of the substrate 11 having a plurality of pins (represented by solid black bars in the sectional view of FIG. 2B; e.g., see 113) that connect nodes of the packaged module 10 to components that are external to the packaged module 10. A pin may be a pad or other means for electrically connecting nodes and components in the present embodiments.

FIG. 2C shows a top plan view of a packaged module 20 for power conversion in accordance with an embodiment of the present invention. FIG. 2D illustratively shows a cross-sectional view of the packaged module 20 taken along the sectional line A-A′ in the top plan view of FIG. 2C in accordance with an embodiment of the present invention. Those skilled in the art should understand that most of the above descriptions to the packaged module 10 made with reference to FIG. 2A and FIG. 2B are applicable to the packaged module 20 in the examples of FIG. 2C and FIG. 2D. Difference in one aspect may lie in that, in the packaged module 20, the electrically conductive coil 13 may have a bridge shape formed as a single-turn winding in the form of a conductive spread sheet wound along a predetermined direction (e.g., along the y axis direction in the examples of FIG. 2C and FIG. 2D), which may be beneficial for further reducing a physical size of the packaged power module 20 and a cost for manufacturing the same. It can be easily understood that the electrically conductive coil 13 formed to have a winding having a single turn may not be limited to have a bridge shape, but may be wound in the predetermined direction in other suitable shapes such as a substantially rectangular shape, a substantially half oval shape, etc. For example, it is illustrated in FIG. 2E that the electrically conductive coil 13 includes a winding having a single turn in the form of a conductive spread sheet wound along the predetermined direction (e.g., along the y axis direction in the example of FIG. 2E) in a substantially rectangular shape. For another example, it is illustrated in FIG. 2F that the electrically conductive coil 13 includes a winding having a single turn in the form of a conductive spread sheet wound along the predetermined direction (e.g., along the y axis direction in the example of FIG. 2F) in a substantially half oval shape. The electrically conductive coil 13 in the form of a one-turn or single-turn winding may, in another aspect, have a lower DCR and be beneficial to supporting higher current or high power that can be processed by the packaged power module 20. A bottom side of the substantial body 13S and a bottom side of the coil terminals (e.g., the first coil terminal 131 and the second coil terminal 132) of the electrically conductive coil 13 are substantially flat so that the electrically conductive coil 13 can be more easily mounted on the substrate 11.

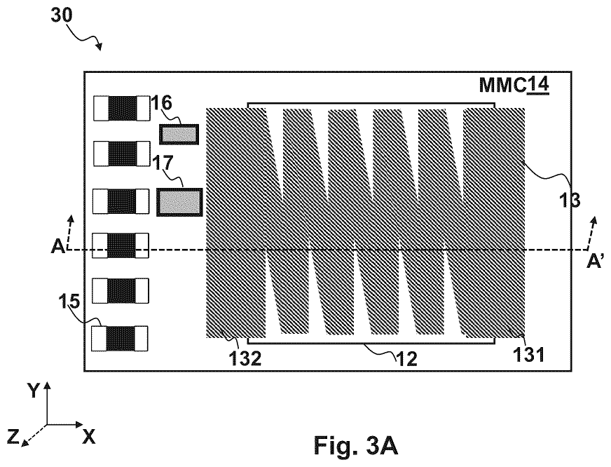

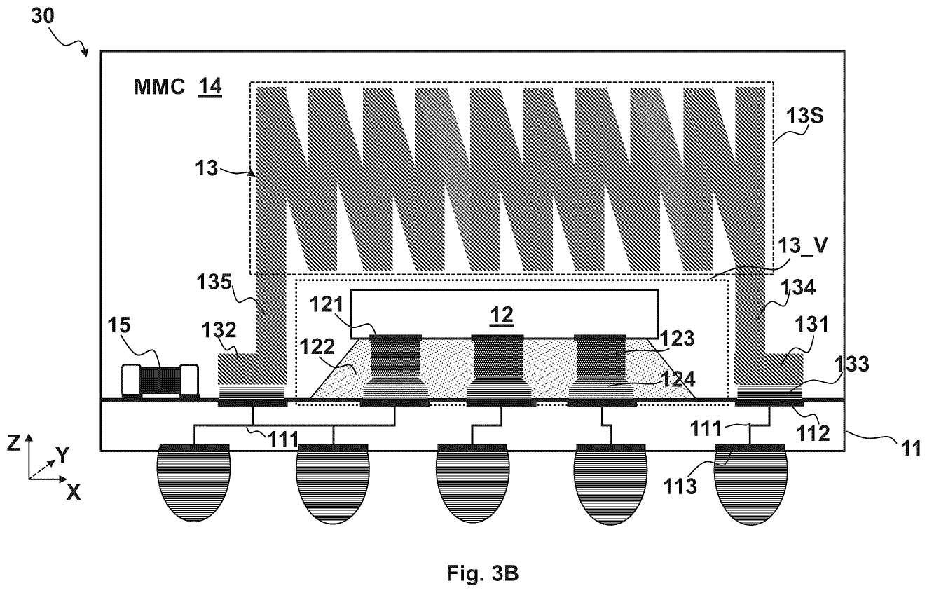

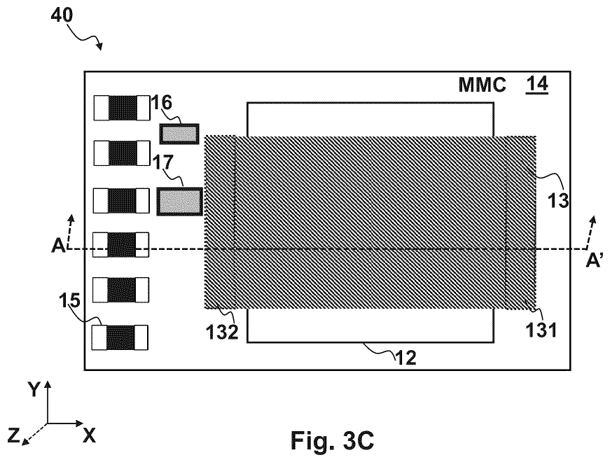

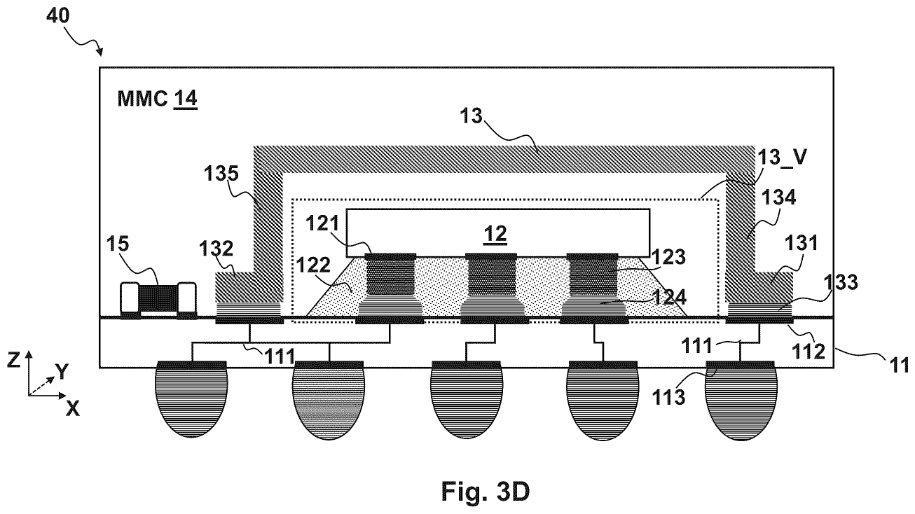

FIG. 3A illustratively shows a top plan view of a packaged module 30 for power conversion in accordance with an embodiment of the present invention. FIG. 3B illustratively shows a cross-sectional view of the packaged module 30 taken along the sectional line A-A′ in top plan view of FIG. 3A in accordance with an embodiment of the present invention. Those skilled in the art should understand that most of the above descriptions to the packaged module 10 made with reference to FIG. 2A and FIG. 2B are applicable to the packaged module 30 in the examples of FIG. 3A and FIG. 3B. Difference in one aspect may lie in that, in the packaged module 30, the electrically conductive coil 13 may be placed across the corresponding power switching unit 12 like a flyover. In the packaged module 30, the electrically conductive coil 13 and the corresponding power switching unit 12 may be considered as being arranged in a vertical-stack manner along the z-axis dimension yet vertically spaced apart from each other. In an embodiment, the electrically conductive coil 13 in the packaged module 20 may have leg portions such as a first leg portion 134 and a second leg portion 135 to respectively connect the wound turns to the coil terminals such as the first coil terminal 131 and the second coil terminal 132. The leg portions such as the first leg portion 134 and the second leg portion 135 are integrally formed with the coil terminals and the wound turns of the electrically conductive coil 13. Each one of the coil terminals may be integrally connected with a coil terminal of the electrically conductive coil 13 by a bending portion of the coil wire in some embodiments. The leg portions such as the first leg portion 134 and the second leg portion 135 may also help to support and vertically elevate the substantial body 13S of the electrically conductive coil 13 to create a vertical space 13_V between the substantial body 13S of the electrically conductive coil 13 and the substrate 11 so that the corresponding power switching unit 12 may be placed in that vertical space 13_V. The packaged module 30 may advantageously have further reduced physical dimension with higher packaging volume utilization efficiency and higher integration density and/or power density.

FIG. 3C shows a top plan view of a packaged module 40 for power conversion in accordance with an embodiment of the present invention. FIG. 3D illustratively shows a cross-sectional view of the packaged module 40 taken along the sectional line A-A′ in top plan view of FIG. 3C in accordance with an embodiment of the present invention. Those skilled in the art should understand that most of the above descriptions to the packaged module 30 made with reference to FIG. 3A and FIG. 3B are applicable to the packaged module 40 in the examples of FIG. 3C and FIG. 3D. Difference in one aspect may lie in that, in the packaged module 40, the electrically conductive coil 13 may have a bridge shape formed as a one-turn winding placed over and across the corresponding power switching unit 12 like a flyover, which may be beneficial for further reducing physical size of the packaged power module 40.

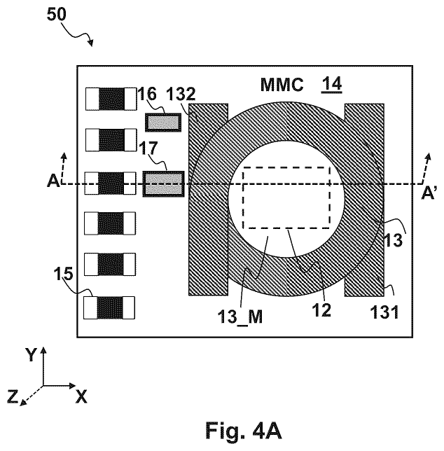

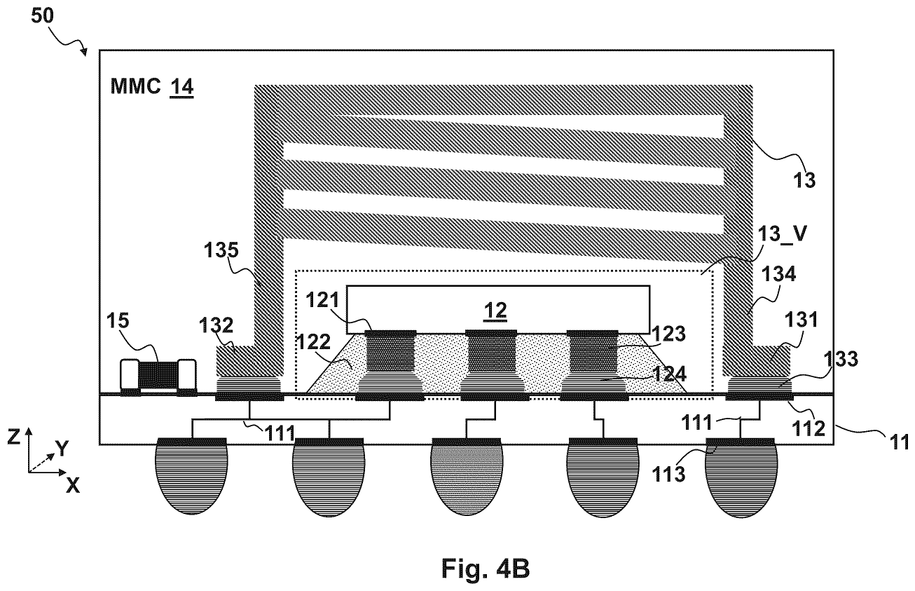

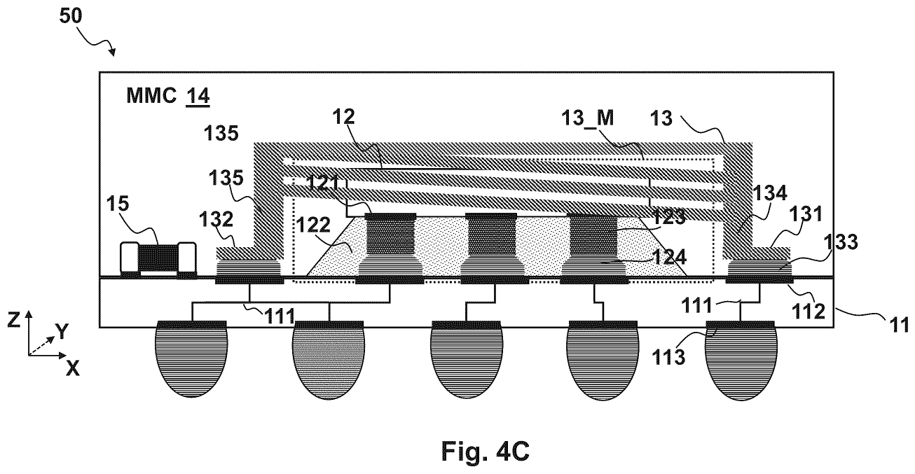

FIG. 4A illustratively shows a top plan view of a packaged module 50 for power conversion in accordance with an embodiment of the present invention. FIG. 4B illustratively shows a cross-sectional view of the packaged module 50 taken along the sectional line A-A′ in top plan view of FIG. 4A in accordance with an embodiment of the present invention. Those skilled in the art should understand that most of the above descriptions to the packaged module 30 made with reference to FIG. 3A and FIG. 3B are applicable to the packaged module 50 in the examples of FIG. 4A and FIG. 4B. Difference in one aspect may lie in that, in the packaged module 50, the electrically conductive coil 13 may be of helix shape having multiple turns wound along the z-axis direction (i.e., direction along the height of the packaged module) to form e.g., one or more windings of an inductive energy storage device, for instance the inductive energy storage device 120 of the power management apparatus 100. Although there is one winding illustrated out in the examples of FIG. 4A and FIG. 4B, it should be understood that more windings may be formed according to practical application requirements. In an embodiment, the electrically conductive coil 13 and the corresponding power switching unit 12 may still be arranged in a vertical-stack manner along the z-axis dimension in the packaged module 50. In an embodiment, for example, the electrically conductive coil 13 in the packaged module 50 may be placed across the corresponding power switching unit 12 like a flyover, and may have a first leg portion 134 and a second leg portion 135 to respectively connect the wound turns to the first coil terminal 131 and the second coil terminal 132. The first leg portion 134 and the second leg portion 135 may also help to create a vertical space 13_V between the electrically conductive coil 13 and the substrate 11 so that the corresponding power switching unit 12 may be placed in that vertical space 13_V.

FIG. 4C illustratively shows a cross-sectional view of the packaged module 50 taken along the sectional line A-A′ in top plan view of FIG. 4A in accordance with an alternative embodiment of the present invention. In such an alternative embodiment, for example, the power switching unit 12 may be disposed inside a hollow space 13_M surrounded by the wound turns of the electrically conductive coil 13 in the packaged module 50. That is, the electrically conductive coil 13 in this example may be placed around the corresponding power switching unit 12 with the wound turns of the electrically conductive coil 13 surrounding the corresponding power switching unit 12 for instance. This may further help to improve the packaging volume utilization efficiency and thereby further reducing a physical dimension of the packaged module 50 with increased integration density and/or power density.

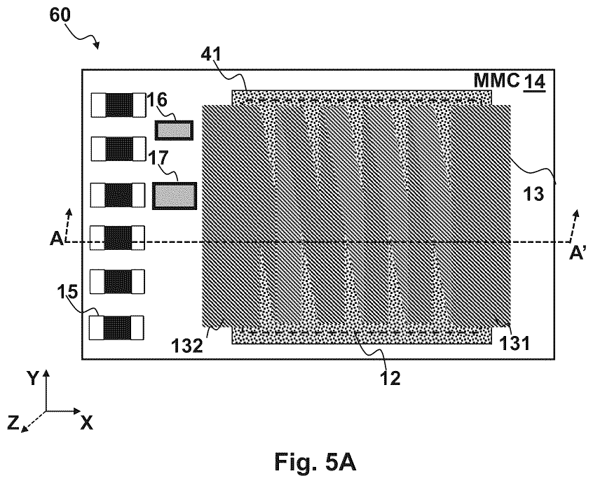

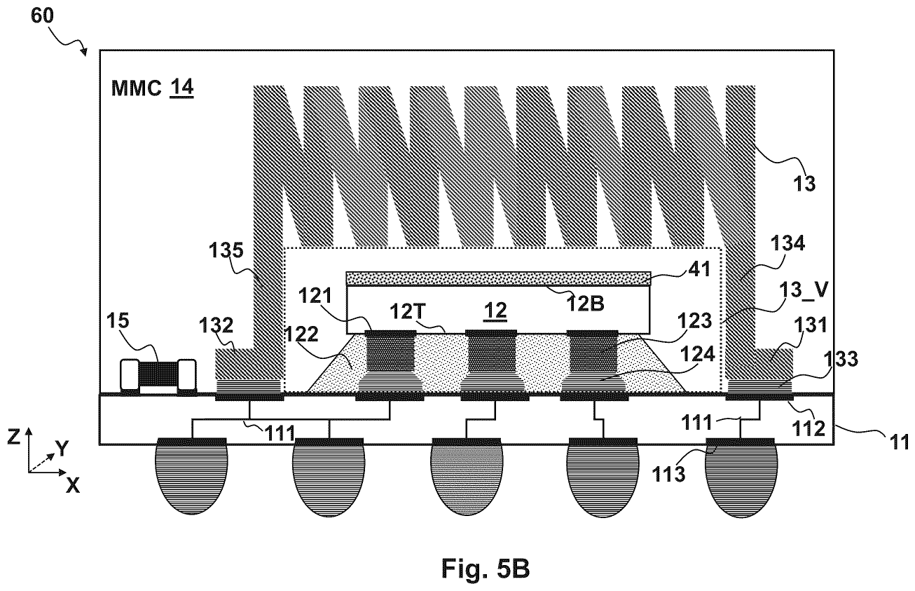

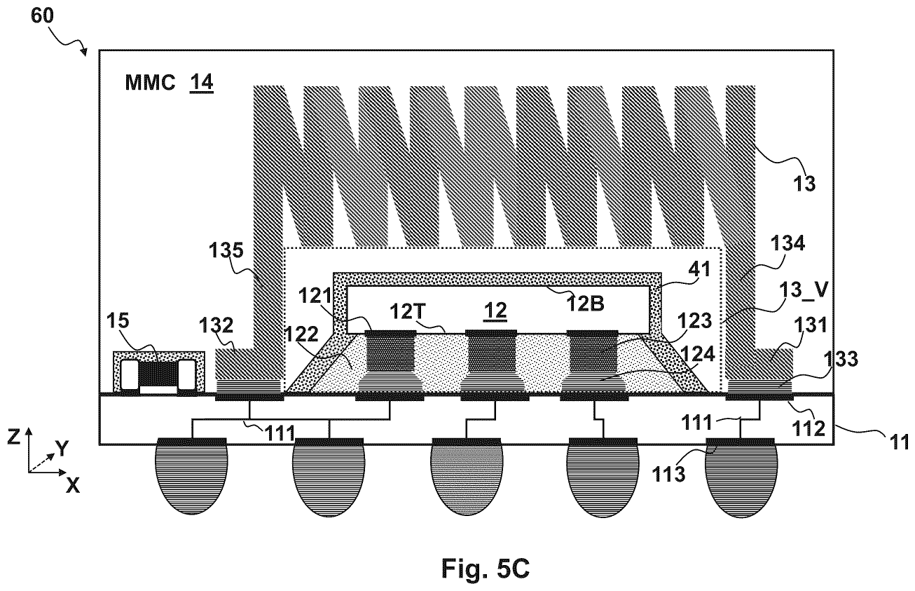

FIG. 5A illustratively shows a top plan view of a packaged module 60 for power conversion in accordance with an embodiment of the present invention. FIG. 5B illustratively shows a cross-sectional view of the packaged module 60 taken along the sectional line A-A′ in top plan view of FIG. 5A in accordance with an embodiment of the present invention. FIG. 5C illustratively shows a cross-sectional view of the packaged module 60 taken along the sectional line A-A′ in top plan view of FIG. 5A in accordance with an alternative embodiment of the present invention. Those skilled in the art should understand that most of the above descriptions to the packaged module 30 made with reference to FIG. 3A and FIG. 3B are applicable to the packaged module 60 in the examples of FIG. 5A, FIG. 5B and FIG. 5C. Difference in one aspect may lie in that, a non-magnetic protection layer 41 may be formed to at least shield a back surface 12B of the power switching unit 12 in the packaged module 60 as illustrated in the example of FIG. 5B, the back surface 12B being opposite to the top surface 12T of the power switching unit 12. Alternatively, the non-magnetic protection layer 41 may be conformally formed atop and to cover components mounted on the substrate 11 as illustrated in the example of FIG. 5C.

When each of the packaged modules according to various embodiments of the present invention is in operation for instance when being used in an application system, current flows through the electrically conductive coil 13, and the inductive energy storage device that includes the electrically conductive coil 13 and the MMC 14 may generate an amount of heat which may affect a die junction temperature or an operation die temperature of the power switching unit 12. For instance, the heat generated by the inductive energy storage device may cause undesirable extra increment in the die junction temperature of the power switching unit 12, resulting in a degradation of electrical performances of the power switching unit 12.

In one aspect, the non-magnetic protection layer 41 may provide thermal isolation between the power switching unit 12 and the inductive energy storage device. In another aspect, the non-magnetic protection layer 41 may serve as a buffer layer to provide thermo-mechanical compliance between the MMC 14 and components molded therein to relieve stresses during environmental lifetime tests (e.g., temperature cycling, thermal shock, etc.), and thus improve thermo-mechanical reliability of the packaged power modules in accordance with various examples of the present invention. In an embodiment, the non-magnetic protection layer 41 may include a polymeric layer comprising polymer composition that may have high toughness and low thermal conductivity and may at least help to reduce the impact of the heat generated from the inductive energy storage device to the power switching unit 12. In yet another aspect, the MMC 14 includes the magnetic metal particles 143, while the magnetic metal particles 143 may bring damages to the semiconductor die (e.g., silicon die) of the power switching unit 12, the non-magnetic protection layer 41 may help to shield the power switching unit 12 from the damages that the magnetic metal particles 143 in the MMC 14 may bring to.

One of ordinary skill in the art would understand that the non-magnetic protection layer 41 may be applied to other embodiments of the present invention as described in the present disclosure according to various examples such as those described with reference to FIG. 2A to FIG. 4C.

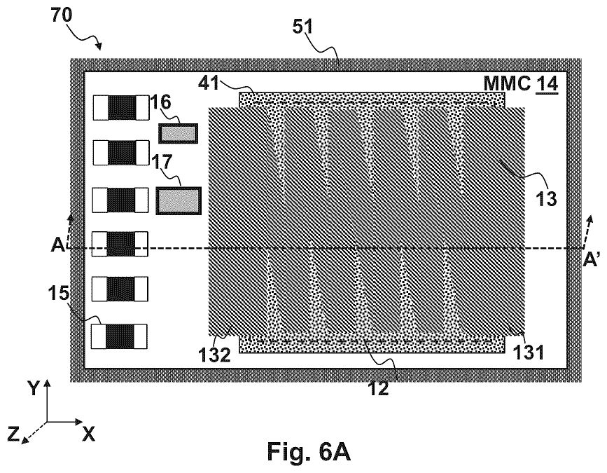

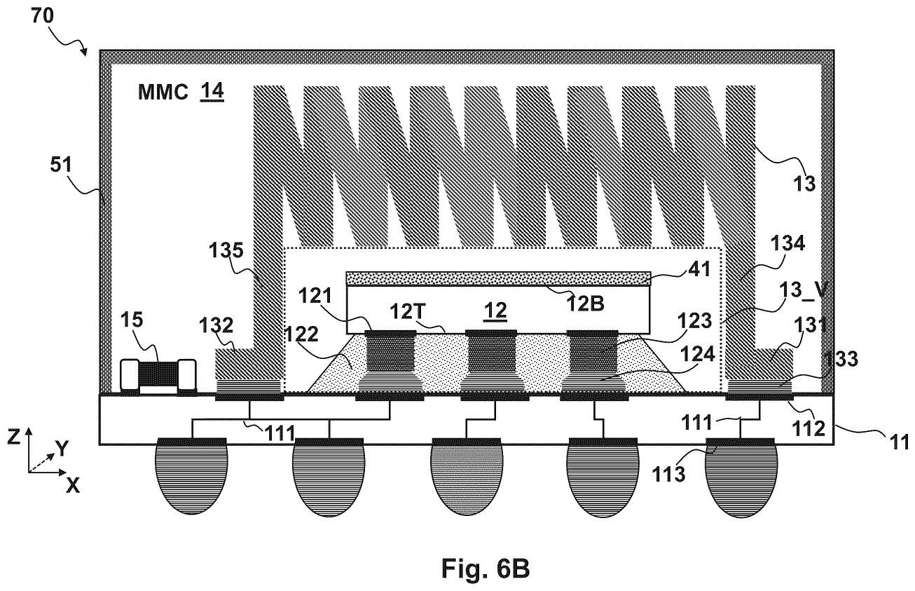

FIG. 6A illustratively shows a perspective top plan view of a packaged module 70 for power conversion in accordance with an embodiment of the present invention. FIG. 6B illustratively shows a cross-sectional view of the packaged module 70 taken along the sectional line A-A′ in the perspective top plan view of FIG. 6A in accordance with an embodiment of the present invention. In the perspective top plan view illustrated in FIG. 6A, top surface of a conductive coating layer 51 is not shown so that pertinent features of the packaged module 70 may be observed. Those skilled in the art should understand that most of the above descriptions to the packaged module 60 made with reference to FIG. 5A and FIG. 5B are applicable to the packaged module 70 in the examples of FIG. 6A and FIG. 6B. In comparison with the package module 60 shown in the examples of FIG. 5A and FIG. 5B, the packaged module 70 may further include the conductive coating layer 51 that coats and shields an outer surface of the MMC 14. The conductive coating layer 51 may be formed of metal or metal alloy such as copper, nickel etc. The conductive coating layer 51 may help to reduce electromagnetic interference (EMI) of the packaged module 70 and enhance heat/thermal dissipation performance, and corrosion resistance performance of the packaged module 70.

One of ordinary skill in the art would understand that the conductive coating layer 51 may be applied to other embodiments of the present invention as described in the present disclosure according to various examples.

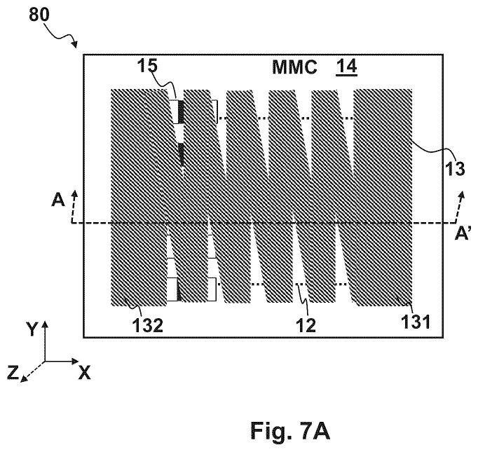

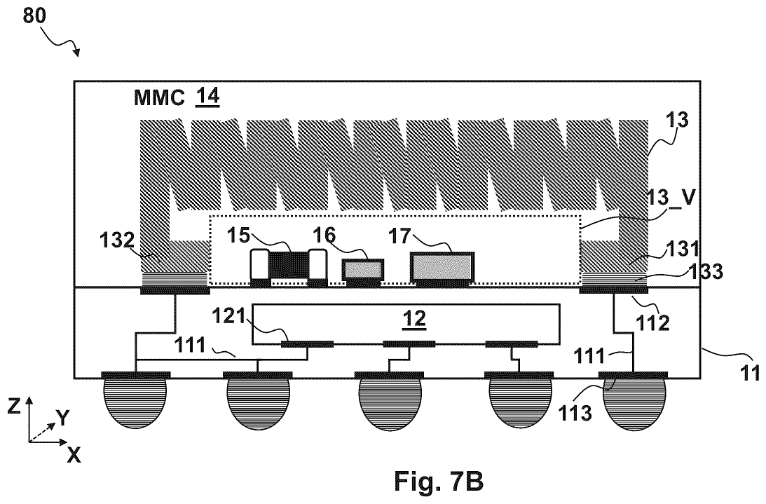

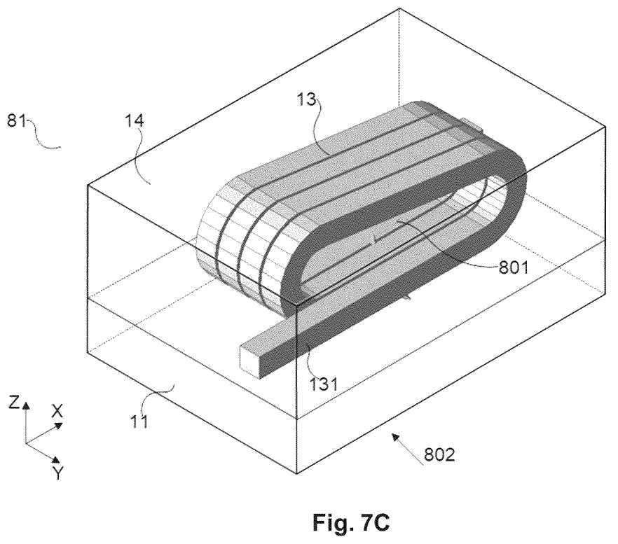

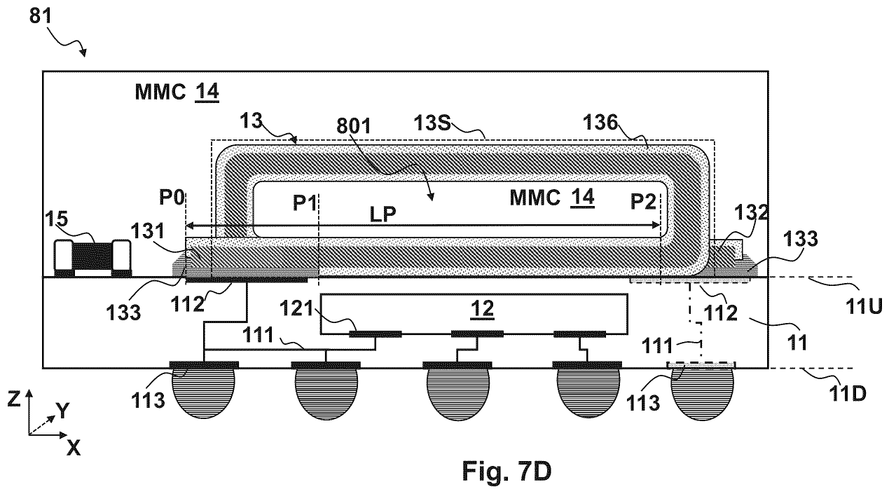

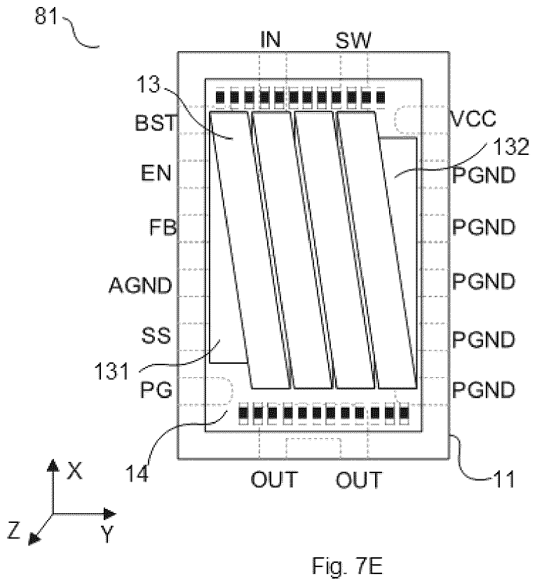

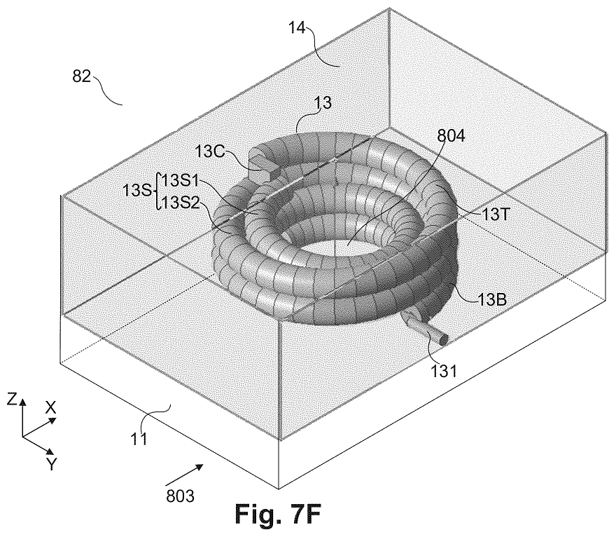

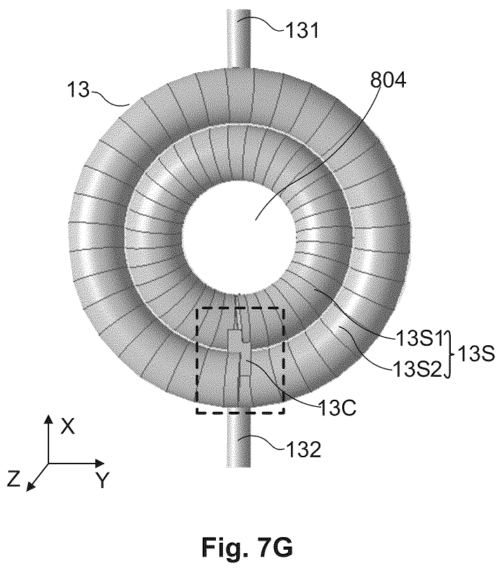

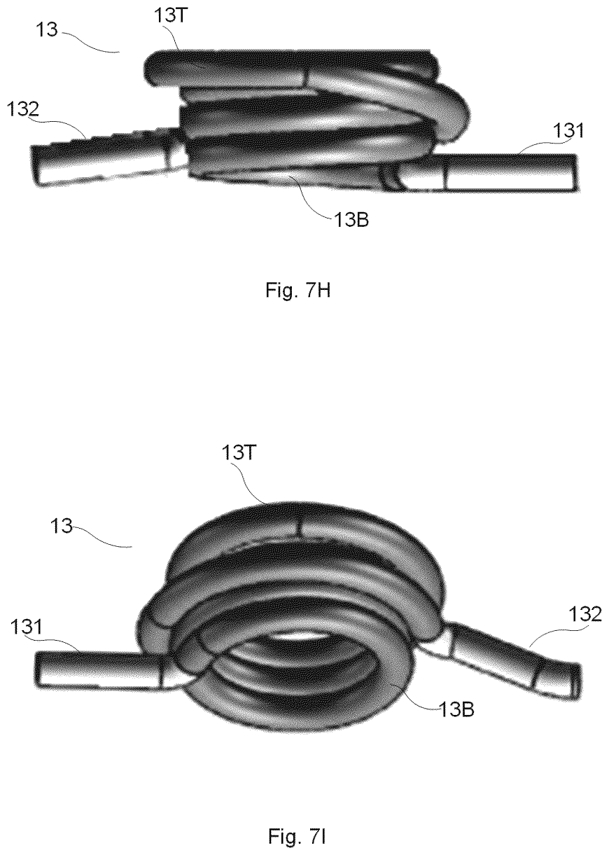

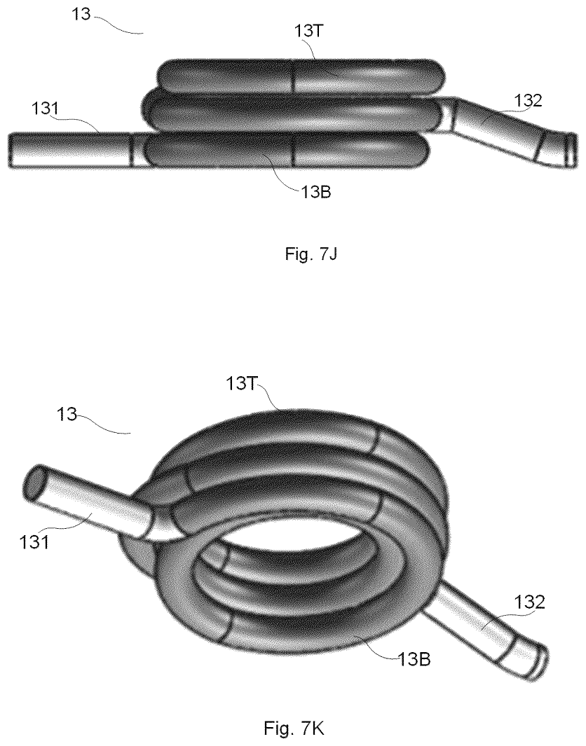

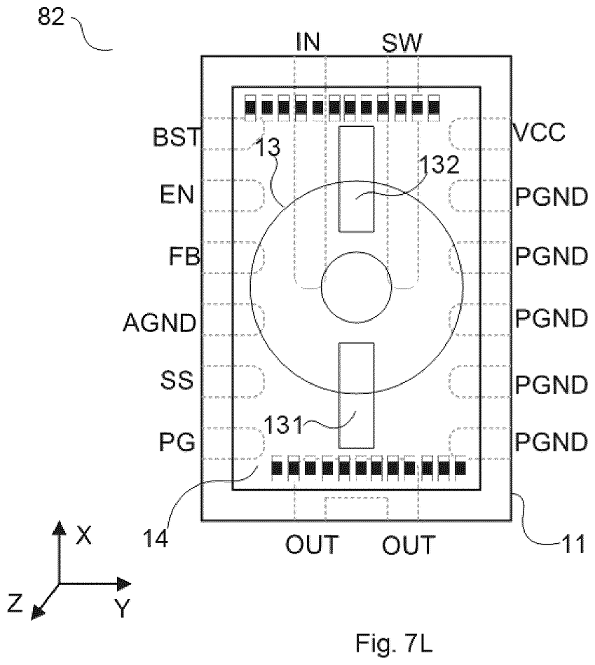

FIG. 7A illustratively shows a perspective top plan view of a packaged module 80 for power conversion in accordance with an embodiment of the present invention. FIG. 7B illustratively shows a cross-sectional view of the packaged module 80 taken along the sectional line A-A′ in the perspective top plan view of FIG. 7A in accordance with an embodiment of the present invention. Those skilled in the art should understand that most of the above descriptions to the packaged module 30 made with reference to FIG. 3A and FIG. 3B are applicable to the packaged module 70 in the examples of FIG. 7A and FIG. 7B. Difference in one aspect may lie in that, the power switching unit 12 may be embedded in the substrate 11 in the packaged module 80. In addition, structures for supporting the power switching unit 12 to be attached to the substrate 11 such as the conductive pillars 123, the underfill 122 and the conductive die attaching materials 124 may be eliminated. With the power switching unit 12 embedded in the substrate 11, more space may be saved out for forming the MMC 14 and the electrically conductive coil 13 (and thus for the inductive energy storage device) and/or for placing other components (such as capacitive devices 15, resistive devices 16 or other components 17 etc.) of the power management apparatus. With such a configuration, the packaged module 80 may have further improved packaging volume utilization efficiency and further reduced physical dimension with increased integration density and/or power density. It also provides more flexibility to design the electrically conductive coil 13 for example providing more flexibility to a placement or mount position, a wound direction of the turns, and/or a shape of the wound turns etc. of the electrically conductive coil 13.

For example, FIG. 7C illustratively shows a perspective 3-dimensional view of a packaged module 81 for power conversion in accordance with an alternative embodiment of the present invention. In the perspective 3-dimensional view of FIG. 7C, except the electrically conductive coil 13 embedded in the MMC 14, other components are not illustrated out in detail so as to not obscure pertinent features of the embodiment, yet these components may be understood with reference to and in conjunction with the drawings of the embodiments already described above. FIG. 7D illustratively shows a perspective side view of the packaged module 81 when inspected from the right-hand side (as indicated by the arrow 802) in the perspective 3-dimensional view of FIG. 7C in accordance with an embodiment of the present invention. FIG. 7E illustratively shows a perspective top plan view of the packaged module 81 for power conversion in accordance with an embodiment of the present invention.

Those skilled in the art should understand that most of the above descriptions to the packaged module 80 made with reference to FIG. 7A and FIG. 7B are applicable to the packaged module 81 in the examples of FIG. 7C to FIG. 7E. Difference in one aspect may lie in that, the electrically conductive coil 13 in the packaged module 81 is illustratively shown to include a multi-turn winding having wiring turns wound along the y-axis direction (i.e., direction along the width of the packaged module 81). A space or volume 801 (referring to FIG. 7C and FIG. 7D) surrounded by the wiring turns of the electrically conductive coil 13 is filled with the MMC 14. The MMC 14 also wraps the electrically conductive coil 13 and any other components mounted to the substrate 11 just as described in the above examples. With the wiring turns of the electrically conductive coil 13 wound along the y-axis direction (i.e., direction along the width of the packaged module 81) or the x-axis direction (i.e., direction along the length of the packaged module 81), it may facilitate a process of encapsulating the packaged module 81 with the MMC 14 by a transfer molding process for instance. It can be understood that in the examples of FIG. 7C to FIG. 7E, a size of the space or volume 801 is related to a size of the electrically conductive coil 13, which is one of the factors influencing the inductance of the inductive energy storage device. Embedding the power switching unit 12 in the substrate 11 and having the wiring turns of the electrically conductive coil 13 wound along the y-axis direction (i.e., direction along the width of the packaged module) may advantageously allow the size of the space or volume 801 or the size of the electrically conductive coil 13 being enhanced under given limited size of the packaged module, which in turn can further help to increase the inductance of the inductive energy storage device and improve the performance of the packaged module with given limited dimension.

As can be understood with reference to FIG. 7C and FIG. 7D, in some embodiments, the substantial body 13S of the electrically conductive coil 13 may not be vertically spaced apart from the first surface 11U of the substrate 11. A bottom side of the substantial body 13S of the electrically conductive coil 13 may be substantially flat, which may facilitate a mounting of the electrically conductive coil 13 on to the substrate 11, for example with the substantial body 13S directly disposed on the first surface 11U of the substrate 11. The coil terminals are substantially coplanar with each other. Each one of the coil terminals (e.g., the first coil terminal 131 and the second coil terminal 132 for each winding) is integrally formed as part of a flat portion of a wiring turn of the electrically conductive coil 13. For this situation, the leg portions such as the first leg portion 134 and the second leg portion 135 can be omitted. Advantageously, this would further reduce the size of the packaged module 81 especially in the z-axis (i.e., height) dimension for example. This would also enhance a mounting yield and a mounting efficiency of mounting the electrically conductive coil 13 on to the substrate 11, with a surface mount technology (“SMT”) for example, and further reduce the complexity and cost of manufacturing and production, which is long desired need to address since there are practically tough challenges for successfully and productively mounting the electrically conductive coil 13 to satisfy the requirements of massive production as can be well understood by those of ordinary skill in the art, which has been stated above and needs not to be repeated here again.

The electrically conductive coil 13 is directly mounted onto the substrate 11 with the coil terminals (e.g., the first coil terminal 131 and the second coil terminal 132) being directly attached to corresponding pads (e.g., see 112) on the first surface 11U of the substrate 11 for example by a conductive attaching material (e.g., solder paste) 133. The thin insulation layer 136 coating the electrically conductive coil 13 is stripped at least at portions (e.g., at bottom surfaces) of the coil terminals (e.g., the first terminal 131 and the second coil terminal 132 in the present examples) so that the coil 13 is suitable to be directly attached to the substrate 11 with each one of the coil terminals having an exposed area free of coverage from the thin insulation layer 136 and configured to provide availability for electrical connections/couplings, which could be better understood with reference to FIG. 7D. The exposed area of each one of the coil terminals may spread from an end edge P0 of each coil terminal to a position that may be flexibly controlled to land in a scope from a minimum position P1 to a maximum position P2 located on the flat portion that each one of the coil terminals is integrally formed with. The minimum position P1 is designed according to a size of the corresponding pad (e.g., see 112) that each one of the coil terminals is to be attached to so that the exposed area of each one of the coil terminals is no smaller than the corresponding pad. For instance, the minimum position P1 in an embodiment is substantially located at ⅓ of a length LP of the flat portion away from the end edge P0. The maximum position P2 is substantially located at an entire length LP of the flat portion away from the end edge P0, a position right before the flat portion goes bent for being wound up. In this fashion, it is beneficial to effectively control and prevent solder leaking during the mounting process which may result in device damage or short.

In some other embodiments, the substantial body 13S of the electrically conductive coil 13 may be vertically spaced apart from the first surface 11U of the substrate 11, similar as illustrated in the examples of FIG. 7A and FIG. 7B. The electrically conductive coil 13 is formed as a flat-wire multi-turn winding in the examples of FIG. 7C to FIG. 7E. However, the electrically conductive coil 13 can alternatively be formed as a round-wire multi-turn winding.

Reference is now made to FIG. 7E. In this example, at the first surface 11U of the substrate 11, the electrically conductive coil 13 is mounted thereon with the MMC 14 molding the packaged module 81. At the second surface 11D or the pin side of the substrate 11, the packaged module 81 may include an input pin IN and a switch pin SW disposed at a first peripheral side of the packaged module 81. Output pins OUT (e.g., two output pins illustrated in FIG. 7E) are disposed at a second peripheral side which is opposite to the first peripheral side of the packaged module 81. The packaged module 81 may further include a bootstrap pin BST, an enable pin EN, a feedback pin FB, a signal ground pin AGND, a soft start pin SS, and a power good pin PG disposed at a third peripheral side of the packaged module 81. The packaged module 81 may further include an internal supply output pin VCC and a plurality of (e.g., five) power ground pins PGND disposed at a fourth peripheral side which is opposite to the third peripheral side of the packaged module 81. The input pin IN may be configured to receive an input voltage VIN. The switch pin SW may be electrically coupled to the power switching unit 12 and the electrically conductive coil 13. The two output pins OUT are connected together inside the packaged module 81 and may be configured to provide an output voltage VOUT. The bootstrap pin BST may be configured with a capacitor connected between the switch pin SW and the bootstrap pin BST pin to form a floating power supply for a driver inside the packaged module 81 for example. The enable pin EN can be configured to enable or disable the packaged module 81. The feedback pin FB can be configured to set the output voltage VOUT for example when connected to a tap of an external resistor divider that is connected between the output pins OUT and the power ground pins PGND. The signal ground pin AGND is electrically connected to the power ground pins PGND in PCB layout. The soft start pin SS may be configured to set a soft-start time for the packaged module 81 to avoid a start-up inrush current. The power good pin PG is an open-drain output that can be configured to provide fault protection information (such as under-voltage protection, over-current protection, over-temperature protection, or an over-voltage condition). The plurality of (e.g., five) power ground pins PGND are electrically connected together inside the package module 81 and can be configured as a reference ground of the output voltage VOUT.

For another example, FIG. 7F illustratively shows a perspective 3-dimensional view of a packaged module 82 for power conversion in accordance with an alternative embodiment of the present invention. In the perspective 3-dimensional view of FIG. 7F, except the electrically conductive coil 13 embedded in the MMC 14, other components are not illustrated out in detail so as to not obscure pertinent features of the embodiment, yet these components may be understood with reference to and in conjunction with the drawings of the embodiments already described above. FIG. 7G illustratively shows an enlarged top plan view of the electrically conductive coil 13 in accordance with an embodiment. FIG. 7H and FIG. 7I respectively illustratively shows enlarged perspective side views of the electrically conductive coil 13 when inspected from the left-hand side (as indicated by the arrow 803) and the side opposite to the left-hand side in the perspective 3-dimensional view of FIG. 7F in accordance with an embodiment of the present invention. FIG. 7J and FIG. 7K respectively illustratively shows enlarged perspective side views of the electrically conductive coil 13 when inspected from the side opposite to the left-hand side in the perspective 3-dimensional view of FIG. 7F in accordance with an alternative embodiment of the present invention. FIG. 7L illustratively shows a perspective top plan view of the packaged module 82 for power conversion in accordance with an embodiment of the present invention.

Those skilled in the art should understand that most of the above descriptions to the packaged module 80 made with reference to FIG. 7A and FIG. 7B are applicable to the packaged module 82 in the examples of FIG. 7F to FIG. 7L. Difference in one aspect may lie in that, the electrically conductive coil 13 in the packaged module 82 is illustratively shown to include a multi-turn winding having wiring turns wound along the z-axis direction (i.e., direction along the height of the packaged module 82). A space or volume 804 (referring to FIG. 7F to FIG. 7L) surrounded by the wiring turns of the electrically conductive coil 13 is filled with the MMC 14. The MMC 14 also wraps the electrically conductive coil 13 and any other components mounted to the substrate 11 just as described in the above examples. With the wiring turns of the electrically conductive coil 13 wound along the z-axis direction (i.e., direction along the height of the packaged module 82), it may facilitate a process of encapsulating the packaged module 82 with the MMC 14 by a compression molding process for instance.

As can be understood with reference to FIG. 7F, in some embodiments, the substantial body 13S of the electrically conductive coil 13 may not be vertically spaced apart from the first surface 11U of the substrate 11. A bottom side of the substantial body 13S of the electrically conductive coil 13 may be substantially directly disposed on the first surface 11U of the substrate 11. An initial wiring turn (or a bottom side wiring turn) 13B of the electrically conductive coil 13 which refers to the wiring turn that would land on the first surface 11U of the substrate 11 is substantially plan, that is the initial wiring turn 13B is wound to have a good planeness, which may facilitate a mounting of the electrically conductive coil 13 on to the substrate 11. The coil terminals are substantially coplanar with each other. Each one of the coil terminals (e.g., the first coil terminal 131 and the second coil terminal 132 for each winding) is integrally formed as part of a wiring turn of the electrically conductive coil 13 and is stretched out from the wiring turn to beyond the substantial body 13S in the x-y plane (width and length plane of the packaged module 82). In some embodiments, one or more of the coil terminals (e.g., the second coil terminal 132) may be vertically bent down to reach a substantially same plane as rest of the coil terminals to enhance their coplanarity, which could be better understood with reference to the exemplary enlarged side views of FIG. 7H to FIG. 7K showing that the second coil terminal 132 is bent vertically down to reach a substantially same plane as the first coil terminal 131. For this situation, the leg portions such as the first leg portion 134 and the second leg portion 135 can be omitted. Advantageously, this would further reduce the size of the packaged module 82 especially in the z-axis (i.e., height) dimension for example. This would also enhance a mounting yield and a mounting efficiency of mounting the electrically conductive coil 13 on to the substrate 11, with a surface mount technology (“SMT”) for example, and further reduce the complexity and cost of manufacturing and production, which is long desired need to address since there are practically tough challenges for successfully and productively mounting the electrically conductive coil 13 to satisfy the requirements of massive production as can be well understood by those of ordinary skill in the art, which has been stated above and needs not to be repeated here again.

In some embodiments, a top side wiring turn 13T of the electrically conductive coil 13 which refers to the wiring turn that is arranged on top of the electrically conductive coil 13 is also substantially plan, that is the top side wiring turn 13T is wound to have a good planeness, which may further facilitate a mounting of the electrically conductive coil 13 on to the substrate 11, especially making it easier for picking the electrically conductive coil 13.

The electrically conductive coil 13 is directly mounted onto the substrate 11 with the coil terminals (e.g., the first coil terminal 131 and the second coil terminal 132) being directly attached to corresponding pads on the first surface 11U of the substrate 11 for example by a conductive attaching material (e.g., solder paste) 133. The thin insulation layer 136 coating the electrically conductive coil 13 is stripped at least at portions (e.g., at bottom surfaces) of the coil terminals (e.g., the first terminal 131 and the second coil terminal 132 in the present examples) so that the coil 13 is suitable to be directly attached to the substrate 11 with each one of the coil terminals having an exposed area free of coverage from the thin insulation layer 136 and configured to provide availability for electrical connections/couplings, which could be better understood with reference to FIG. 7I with the stripped portions or exposed areas illustrated in bright gray and the remained un-stripped portion (e.g., substantially including the substantial body 13S) of the electrically conductive coil 13 illustrated in dark gray.

In some embodiments, the substantial body 13S of the electrically conductive coil 13 may include wiring turns wound into multiple layers as can be inspected from a plane view perpendicular to the direction along which the wiring turns are wound. For instance, in the examples of FIG. 7F to FIG. 7L, the wiring turns are wound into two layers including an inner layer 13S1 and an outer layer 13S2 when inspected from the x-y plane view that is perpendicular to the z-axis direction along which the wiring turns are wound. It may be more apparent and easier to understand when referencing to the enlarged top plan view of the electrically conductive coil 13 illustratively shown in FIG. 7G. However, this is just exemplary and not intended to be limiting as can be well understood by those of ordinary skill in the art. In alternative examples, the wiring turns may be wound into more than two layers according to practical design and application requirements. Each of the multiple layers may include a number of or a set of wiring turns wound along a predetermined direction, for instance the z-axis direction (i.e., direction along the height of the packaged module 82) in the examples of 7F to FIG. 7L. With the electrically conductive coil 13 having wiring turns wound into multiple layers (e.g., 13S1 and 13S2), it may advantageously further increase the inductance of the inductive energy storage device and improve the performance of the packaged module with given limited dimension.

In some embodiments, the multiple layers (e.g., the inner layer 13S1 and the outer layer 13S2) are formed by winding/coiling a single coil wire with the winding/coiling beginning at an end of the coil wire and the wound wiring turns spreading upward to form the inner layer 13S1 and then spreading downward to form the outer layer 13S2, as shown in the example of FIG. 7H and FIG. 7I. In some alternative embodiments, the multiple layers (e.g., the inner layer 13S1 and the outer layer 13S2) are formed by winding/coiling a single coil wire with the winding/coiling beginning at both ends of the coil wire simultaneously, and the wound wiring turns began from one end spreading upward to form the inner layer 13S1 and the wound wiring turns began from the other end spreading downward to form the outer layer 13S2 as shown in the example of FIG. 7J and FIG. 7K.

In still some alternative embodiments, each one of the multiple layers may be formed by winding/coiling a single coil wire and then be connected to each other, for example, every two adjacent layers among the multiple layers of the electrically conductive coil 13 may be connected to each other by a connecting structure 13C (see illustratively shown in FIG. 7G).

In some other embodiments, the substantial body 13S of the electrically conductive coil 13 may be vertically spaced apart from the first surface 11U of the substrate 11, similar as illustrated in the examples of FIG. 7A and FIG. 7B. The electrically conductive coil 13 is formed as a round-wire multi-turn winding in the examples of FIG. 7F to FIG. 7J. However, the electrically conductive coil 13 can alternatively be formed as a flat-wire multi-turn winding.

Reference is now made to FIG. 7L. Descriptions made with reference to FIG. 7E for the packaged module 81 are applicable for the example packaged module 82 in FIG. 7L and will not be repeated here.

One of ordinary skill in the art would understand that for other embodiments of the present invention such as those described with reference to FIG. 2A to FIG. 6B, the power switching unit 12 may alternatively be embedded in the substrate 11 similarly as described with reference to the examples shown in FIG. 7A to FIG. 7L.

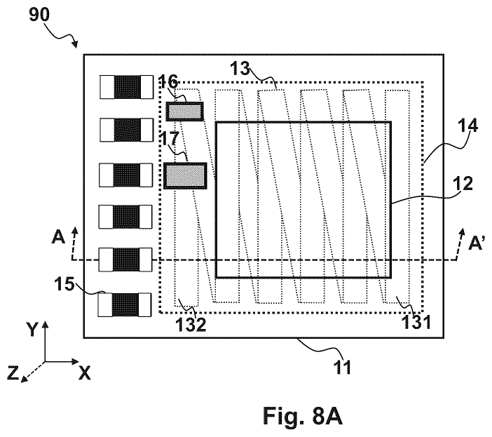

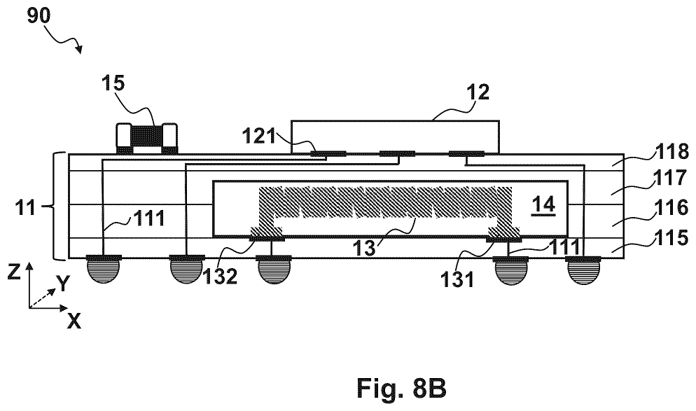

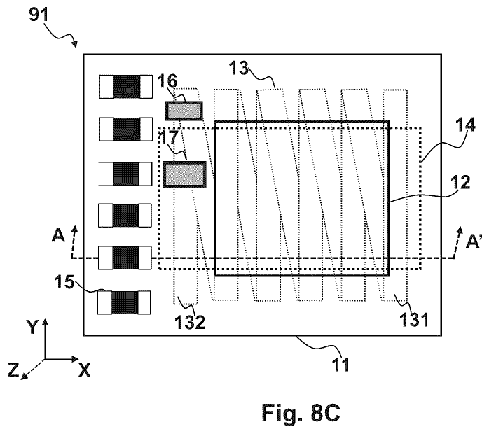

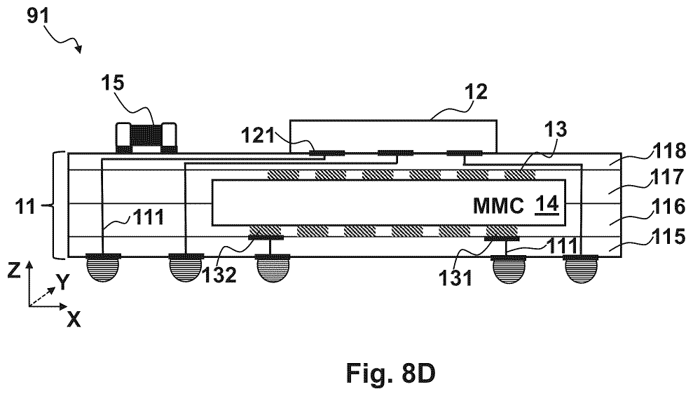

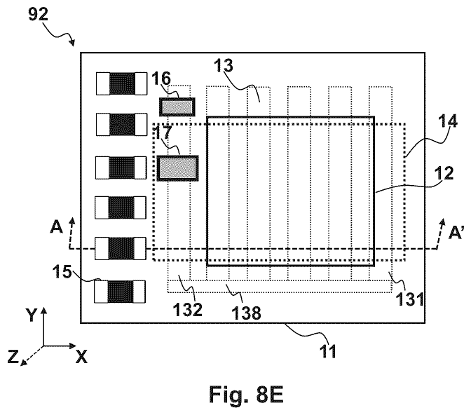

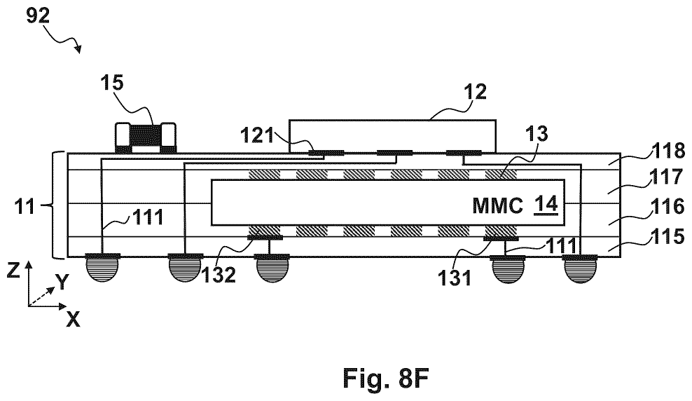

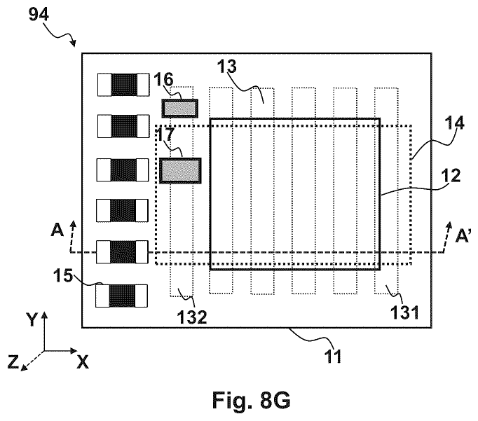

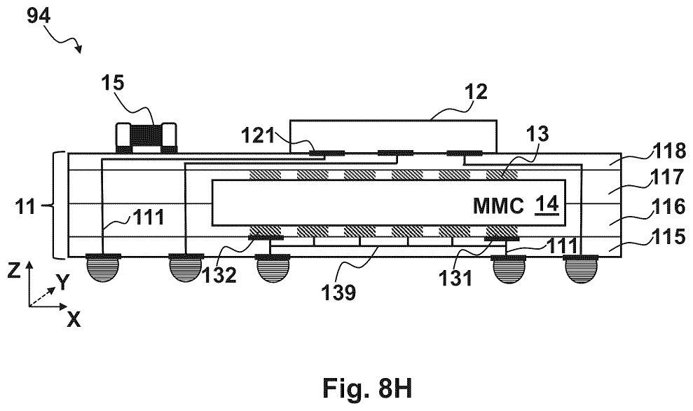

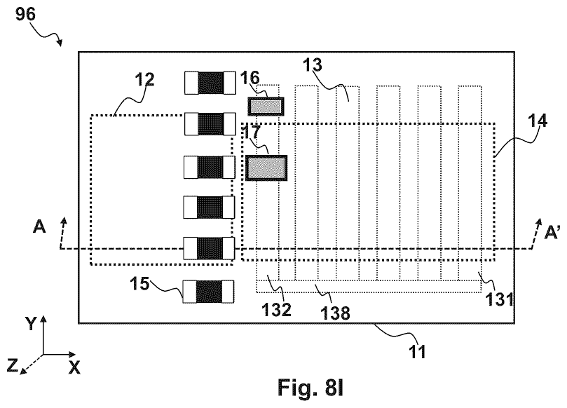

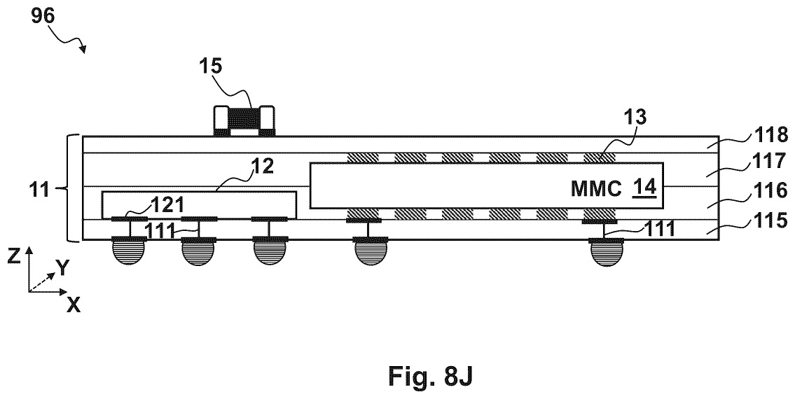

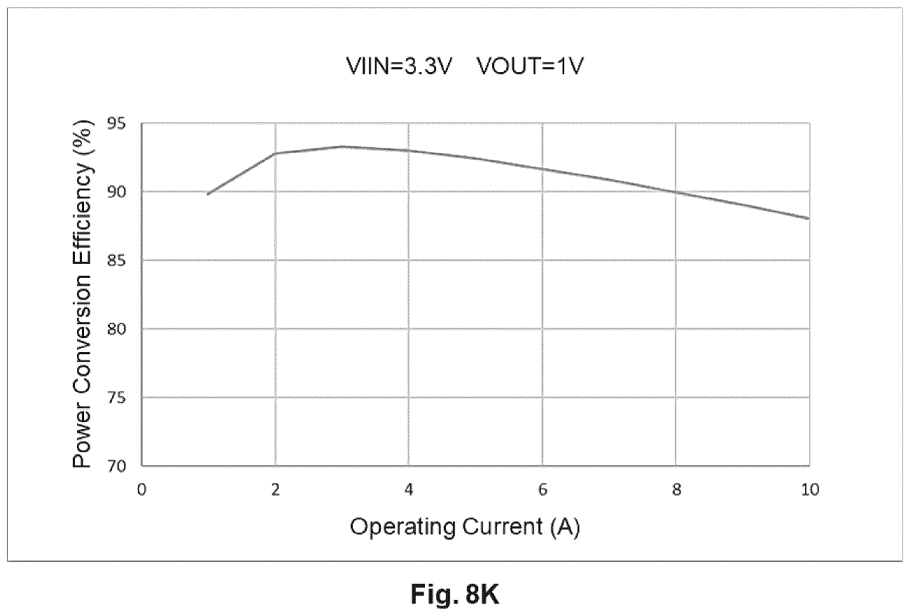

FIG. 8A illustratively shows a perspective top plan view of a packaged module 90 for power conversion in accordance with an embodiment of the present invention. FIG. 8B illustratively shows a cross-sectional view of the packaged module 90 taken along the sectional line A-A′ in the perspective top plan view of FIG. 8A in accordance with an embodiment of the present invention. Those skilled in the art should understand that most of the above descriptions to the packaged module 30 made with reference to FIG. 3A and FIG. 3B are applicable to the packaged module 90 in the examples of FIG. 8A and FIG. 8B. In this example, the substrate 11 is illustratively shown to include multiple substrate layers for instance four substrate layers 115 to 118 are shown. In comparison with the packaged module 30, difference in one aspect may lie in that, the inductive energy storage device including the coil 13 and the MMC 14 encapsulating the coil 13 may be embedded in the substrate 11 in the packaged module 90. For instance, the coil 13 and the MMC 14 may be formed in a second substrate layer 116 and a third substrate layer 117 that are sandwiched between a first substrate layer 115 and a fourth substrate layer 118. With the inductive energy storage device including the coil 13 and the MMC 14 embedded in the substrate 11, the packaged module 90 may have further improved packaging volume utilization efficiency and further reduced physical dimension with increased integration density and/or power density.

FIG. 8C illustratively shows a perspective top plan view of a packaged module 91 for power conversion in accordance with an embodiment of the present invention. FIG. 8D illustratively shows a cross-sectional view of the packaged module 91 taken along the sectional line A-A′ in the perspective top plan view of FIG. 8C in accordance with an embodiment of the present invention. Those skilled in the art should understand that the packaged module 91 may be considered as an alternative embodiment with the inductive energy storage device including the coil 13 and the MMC 14 embedded in the substrate 11, for instance this example may be considered as a variant from the packaged module 90. In comparison with the packaged module 90, difference in one aspect may lie in that, the coil 13 may be formed around the MMC 14 in the packaged module 91. That is, the coil 13 may have turns wound around the MMC 14. In this example, the turns of the coil 13 may be continuously wound around the MMC 14 and thus are connected with each other.

FIG. 8E illustratively shows a perspective top plan view of a packaged module 92 for power conversion in accordance with an embodiment of the present invention. FIG. 8F illustratively shows a cross-sectional view of the packaged module 92 taken along the sectional line A-A′ in the perspective top plan view of FIG. 8E in accordance with an embodiment of the present invention. Those skilled in the art should understand that the packaged module 92 may be considered as an alternative embodiment with the inductive energy storage device including the coil 13 and the MMC 14 embedded in the substrate 11, for instance this example may be considered as a variant from the packaged module 91. In comparison with the packaged module 91, difference in one aspect may lie in that, the coil 13 may have turns discontinuously wound around the MMC 14 in the packaged module 92. In this example, the turns of the coil 13 may be connected together by a coil connecting portion 138.

FIG. 8G illustratively shows a perspective top plan view of a packaged module 94 for power conversion in accordance with an embodiment of the present invention. FIG. 8H illustratively shows a cross-sectional view of the packaged module 94 taken along the sectional line A-A′ in the perspective top plan view of FIG. 8G in accordance with an embodiment of the present invention. Those skilled in the art should understand that the packaged module 94 may be considered as an alternative embodiment with the inductive energy storage device including the coil 13 and the MMC 14 embedded in the substrate 11, for instance this example may be considered as a variant from the packaged module 92. In comparison with the packaged module 92, difference in one aspect may lie in that, the discontinuously wound turns of the coil 13 in the packaged module 94 may be connected together by connecting structures 139 similar to the connecting structures 111 formed in the substrate 11. For instance, in the example of FIG. 8H, it is illustrated that connecting structures 139 formed in the first substrate layer 115 are used to connect the turns of the coil 13 together.

FIG. 8I illustratively shows a perspective top plan view of a packaged module 96 for power conversion in accordance with an embodiment of the present invention. FIG. 8J illustratively shows a cross-sectional view of the packaged module 96 taken along the sectional line A-A′ in the perspective top plan view of FIG. 8I in accordance with an embodiment of the present invention. Those skilled in the art should understand that the packaged module 96 may be considered as an alternative embodiment with both the power switching unit 12 and the inductive energy storage device including the coil 13 and the MMC 14 embedded in the substrate 11, for instance this example may be considered as a variant from the packaged module 92. In comparison with the packaged module 92, difference in one aspect may lie in that, the power switching unit 12 may further be embedded in the substrate 11 in the packaged module 96. For instance, in the example shown in FIG. 8J, it is illustrated that the power switching unit 12 is embedded in the second substrate layer 116 of the substrate 11.

The packaged modules in accordance with various embodiments of the present invention may lead to a 10% to 50% reduction of physical dimension and/or footprints of the packaged modules in comparison with the conventional power converter module with substantially identical functions and/or specifications given to implement. This can improve the efficiency and current density of the packaged modules for power conversion. In another aspect, the cost of the packaged power modules in accordance with various embodiments of the present invention may be lower than the conventional power converter modules.

To provide an example, the packaged modules in accordance with various embodiments of the present disclosure may support an operating current (e.g., a load current provided at the output terminal OUT of a packaged module) ranging from 1A to 4A, with a physical dimension of having a width times a length essentially ranging from 2 mm*2 mm to 2 mm*3 mm and a height essentially ranging from 1.0 mm to 1.5 mm, or alternatively having a width times a length essentially ranging from 2 mm*2 mm to 2 mm*2.2 mm and a height essentially ranging from 1.0 mm to 1.2 mm, which has been greatly shrank compared to conventional power converter modules for supporting the same operating current range. Those of ordinary skill in the art would understand that these designs in physical dimensions of the packaged modules are critical, and any 0.1-millimeter size reduction is derived from the creative labor of the embodiments of the present invention. For instance, the packaged module 82 as described with reference to FIG. 7F to FIG. 7L may be configured to support an operating current ranging from 1A to 4A, wherein the electrically conductive coil 13 may be wound with a round coil wire having a wire diameter no greater than 0.3 mm and wound in a winding of a substantial cylinder-like shape with a cylinder diameter no greater than 1.6 mm. The packaged modules for power conversion to support an operating current ranging from 1A to 4A in accordance with various embodiments of the present disclosure may have a power conversion efficiency peak value higher than 88% up to or higher than 90%. The integrated inductive energy storage device including the MMC 14 and the electrically conductive coil 13 integrated in the packaged modules in accordance with various embodiments of the present disclosure to support an operating current ranging from 1A to 4A may have an inductance up to 2 μH, which would be beneficial to tremendously reducing the DCR of the integrated inductive energy storage device that is greatly desired for low current (e.g., lower than 4A) applications.

To provide another example, the packaged modules in accordance with various embodiments of the present disclosure may support an operating current (e.g., a load current provided at the output terminal OUT of a packaged module) ranging from 4A to 10A, with a physical dimension of having a width times a length essentially ranging from 2 mm*3 mm to 3 mm*4 mm and a height essentially ranging from 1.0 mm to 2 mm, or alternatively having a width times a length essentially ranging from 2 mm*3 mm to 2 mm*4 mm and a height essentially ranging from 1.0 mm to 1.5 mm, which has been greatly shrank compared to conventional power converter modules for supporting the same operating current range. For instance, the packaged module 81 as described with reference to FIG. 7C to FIG. 7E may be configured to support an operating current ranging from 4A to 10A, wherein the electrically conductive coil 13 may be wound with a flat coil wire having a wire thickness ranging from 0.03 mm to 0.3 mm and wound in a winding of a substantial cuboid-like shape with a height essentially ranging from 0.85 mm to 1.85 mm. For another instance, the packaged module 82 as described with reference to FIG. 7F to FIG. 7L may be configured to support an operating current ranging from 4A to 10A, wherein the electrically conductive coil 13 may be wound with a round coil wire having a wire diameter no greater than 0.4 mm and wound in a winding of a substantial cylinder-like shape with a cylinder diameter ranging from 1.6 mm to 2.6 mm, or alternatively the electrically conductive coil 13 may be wound with a round coil wire having a wire diameter of essentially 0.23 mm+0.05 mm and wound in a winding of a substantial cylinder-like shape with a cylinder diameter ranging from 1.6 mm to 1.8 mm. The packaged modules for power conversion to support an operating current ranging from 4A to 10A in accordance with various embodiments of the present disclosure may have a power conversion efficiency peak value higher than 88% up to or higher than 90%. The integrated inductive energy storage device including the MMC 14 and the electrically conductive coil 13 integrated in the packaged modules in accordance with various embodiments of the present disclosure to support an operating current ranging from 4A to 10A may have an inductance up to 1 μH, which would be beneficial to providing good balance between the inductance and the DCR specifications of the integrated inductive energy storage device that is greatly desired for medium current (e.g., 4A to 10A) applications.

To provide still another example, the packaged modules in accordance with various embodiments of the present disclosure may support an operating current (e.g., a load current provided at the output terminal OUT of a packaged module) ranging from 6A to 20A, with a physical dimension of having a width times a length essentially ranging from 2 mm*3 mm to 5 mm*6 mm and a height essentially ranging from 1.2 mm to 3 mm, or alternatively having a width times a length essentially ranging from 2 mm*3 mm to 4 mm*4 mm and a height essentially ranging from 1.2 mm to 2.5 mm, which has been greatly shrank compared to conventional power converter modules for supporting the same operating current range. The packaged modules for power conversion to support an operating current ranging from 6A to 20A in accordance with various embodiments of the present disclosure may have a power conversion efficiency peak value higher than 85% up to or higher than 90%. The integrated inductive energy storage device including the MMC 14 and the electrically conductive coil 13 integrated in the packaged modules in accordance with various embodiments of the present disclosure to support an operating current as high as up to 20A may have an inductance up to 1 μH, which would be beneficial to providing good balance between the inductance and the DCR specifications of the integrated inductive energy storage device that is greatly desired for relatively high current (e.g., 6A to 20A) applications.

For example, FIG. 8K illustrates a waveform diagram illustrating a curve of the power conversion efficiency of a packaged module versus an operating current (e.g., a load current provided at the output of the packaged module) of the packaged module in accordance with an embodiment of the present disclosure. In this example, test or simulation is performed for a packaged module such as described with reference to the examples of FIG. 7F to FIG. 7L with the exemplary parameters VIN=3.3V and VOUT=1V. It can be seen from FIG. 8K that the packaged module has a power conversion efficiency peak value higher than 88% up to or higher than 90%.

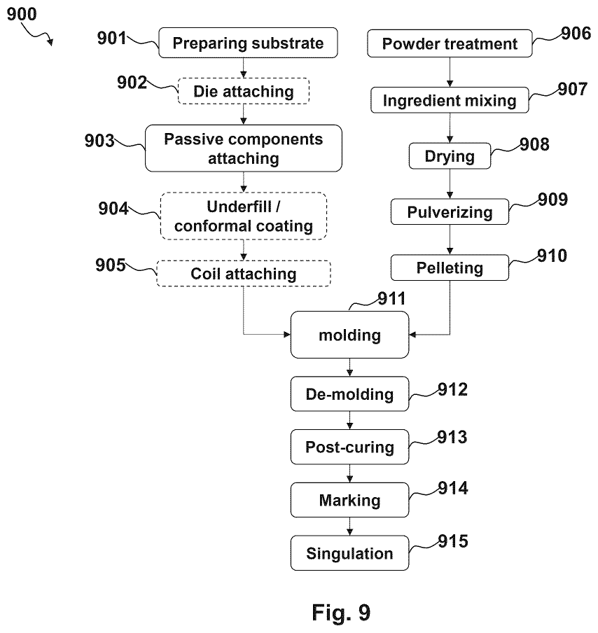

FIG. 9 illustrates a process flow chart showing a method 900 for manufacturing a packaged module for power conversion in accordance with an embodiment of the present invention.

At step 901, a substrate panel adapted to be used for massive or batch production of an array of packaged modules in accordance with various examples of the present invention may be prepared and provided. The substrate panel may be adapted to be singulated in subsequent manufacturing step(s) to form a substrate (such as the substrate 11 as described above in accordance with various embodiments) of each single packaged module of the array of packaged modules to be manufactured. In some embodiments, various structures (such as interconnection structures and/or the electrically conductive wiring structures 111) which are adapted to be correspondingly used for each single packaged module may be pre-formed or embedded in the substrate panel. In some embodiments, some components (such as the power switching unit 12 and/or the inductive energy storage device, etc.) which are adapted to be correspondingly used for each single packaged module may further be pre-formed or embedded in the substrate panel. For instance, for embodiments with the power switching unit 12 embedded in the substrate 11, an array of power switching units 12 and corresponding wiring structures 111 may be pre-embedded in the substrate panel provided at step 901. For another instance, for embodiments with the inductive energy storage device embedded in the substrate 11, such as the structures illustrated in the examples of FIG. 8A to FIG. 8J, an array of coils 13 and associated MMC 14 ( ) and corresponding wiring structures 111 may be pre-embedded in the substrate panel provided at step 901.

At step 902, an array of semiconductor dies may be attached to the substrate panel. Each one semiconductor die of the array of semiconductor dies may have at least one power switching unit 12 fabricated therein. For example, each one semiconductor die having the power switching unit 12 with conductive pads 121 and/or conductive pillars 123 formed at a top surface of the semiconductor die may be attached to the substrate panel via a conductive die attaching material 124 with the top surface down facing the substrate panel. One of ordinary skill in the art would understand that for embodiments with the power switching unit 12 embedded in the substrate 11, die attaching at step 902 may be omitted.

At step 903, other components such as the passive components including but not limited to capacitive devices 15, resistive devices 16 or other devices 17 etc. of each single packaged module to be manufactured may be attached to the substrate panel.

At step 904, an underfill material 122 may be used to fill cavities between the power switching unit 12 and the substrate panel to provide insulation and/or to provide thermo-mechanical compliance. In an example, for embodiments where each single packaged module to be manufactured may further include the non-magnetic protection layer 41, a conformal coating process for coating or depositing the non-magnetic protection layer 41 on components mounted on the substrate panel may optionally be performed at step 904.

At step 905, the coil 13 corresponding to each one semiconductor die having the at least one power switching unit 12 fabricated therein may be attached to the substrate panel. Placement of the coil 13 may be flexibly designed as described in the examples described with reference to FIG. 2A to FIG. 8B. One of ordinary skill in the art would understand that for embodiments with the inductive energy storage device embedded in the substrate 11, attaching of the coil 13 at step 905 may be omitted.

At step 906, a process of magnetic powder treatment of the magnetic metal particles 143 may be executed. In this process, the magnetic metal particles 143 are treated such that an insulation coating layer 144 coats and encapsulates each one of the magnetic metal particles 143 to form coated magnetic particles 142.

At step 907, ingredients of the MMC 14 may be mixed to form a mixture of magnetic materials. The ingredients may include the non-magnetic material 141 and the coated magnetic particles 142 in an exemplary embodiment. In this process, the coated magnetic particles 142 may be dispersed throughout the non-magnetic material 141, the mixture of magnetic materials may be in fluid or gelatinous status. In other words, a composite magnetic material in fluid or gelatinous form may be obtained after the ingredient treatment process of 907.

At step 908, a drying process may be executed to dry the mixture of magnetic materials.

At step 909 and step 910, the dried mixture of magnetic materials may be pulverized and/or pelleted to form a powder or pelleted magnetic molding compound 14 that is compatible with a molding process such as a transfer molding process or a compression molding process etc.

At step 911, a molding process may be performed to encapsulate the substrate panel and/or components needing to be molded with the magnetic molding compound 14. One of ordinary skill in the art would understand that the molding process or molding method is definitely not limited to the examples given here. One of ordinary skill in the art would also understand that for embodiments with the inductive energy storage device embedded in the substrate 11, the molding process may alternatively be performed at the step 901 during preparing the substrate panel.

At step 912, a demolding process is executed after the molding process.

At step 913, a post curing process may be performed after the demolding process so that the MMC 14 is fully cured to improve thermal stability and reduce the moisture absorption.

At step 914, a marking process may be executed to the molded substrate panel.

At step 915, the substrate panel with components mounted thereon and/or embedded therein may be singulated according to the marks made in step 914 and singulated packaged modules in accordance with various embodiments such as those described with reference to FIG. 2A to FIG. 8K may be obtained.

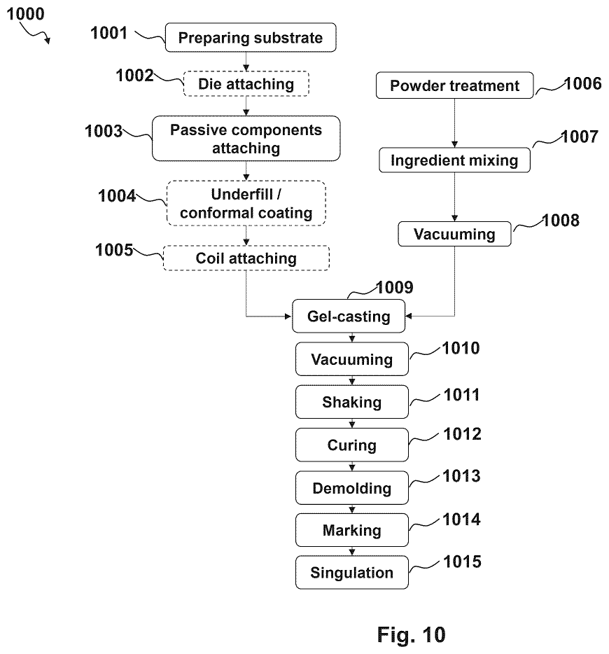

FIG. 10 illustrates a process flow chart showing a method 1000 for manufacturing a packaged module for power conversion in accordance with an alternative embodiment of the present invention.

Steps 1001 to 1005 may be respectively corresponding to the steps 901 to 905. That is, descriptions to the steps 901 to 905 are respectively applicable to the steps 1001 to 1005 and may not be addressed in detail again here.

Steps 1006 and 1007 may be respectively corresponding to the steps 906 and 907. That is, descriptions to the steps 906 to 907 are respectively applicable to the steps 1006 to 1007 and may not be addressed in detail again here.

At step 1008, a vacuuming process may be executed to eliminate air bubbles in the fluid or gelatinous mixture of magnetic materials obtained at step 1007.

At step 1009, a molding process such as a gel-casting molding process may be performed to fill or perfuse the mixture of magnetic materials in fluid or gelatinous status so that the composite magnetic material in fluid or gelatinous form is used as the magnetic molding compound 14 and filled in the packaged modules in accordance with various embodiments of the present invention. One of ordinary skill in the art would understand that for embodiments with the inductive energy storage device embedded in the substrate 11, the molding process may alternatively be performed at the step 1001 during preparing the substrate panel.

At steps 1010 and 1011, a vacuuming process and a shaking process are performed to eliminate air bubbles in the magnetic molding compound 14 in paste or gelatinous form and to obtain a smooth top surface.

At steps 1012 and 1013, a curing process (e.g., a heated curing process) and a demolding process may be executed.

At step 1014, a marking process may be executed to the molded substrate panel.

At step 1015, the substrate panel with components mounted thereon and/or embedded therein may be singulated according to the marks made in step 1014 and singulated packaged modules in accordance with various embodiments such as those described with reference to FIG. 2A to FIG. 8J may be obtained.

The methods for manufacturing the packaged modules for power conversion in accordance with various embodiments of the present invention may be implemented without requiring of special equipment that is different from equipment for manufacturing the conventional power converter modules, thereby can save many efforts and costs for the process and the assembly proving.

In accordance with an exemplary embodiment, a composite magnetic material is further disclosed. The composite magnetic material in an embodiment includes a composite non-magnetic material (MA) and coated magnetic particles (MB) dispersed in the composite non-magnetic material (MA). The coated magnetic particles (MB) may alternatively be referred to as a magnetic filler that disperses in the composite non-magnetic material (MA) which may also be referred to as a non-magnetic polymer matrix. The composite magnetic material in an embodiment may provide a high relative magnetic permeability with a relatively low core-loss. For instance, samples of the composite magnetic material according to some embodiments of the present disclosure may have a relative magnetic permeability no lower than 16 at a frequency of no greater than 100 MHz. For further instance, samples of the composite magnetic material according to some embodiments of the present disclosure may have a low core-loss essentially of 15 KW/m³ to 60 kW/m³ at 5mT, wherein mT represents the magnetic unit milli Tesla.

The composite magnetic material according to various embodiments of the present disclosure could thus provide good relative magnetic permeability for applications requiring high energy/power efficiency, low power loss and lower dimensions such as for data center, cloud computing, Artificial Intelligence (“AI”), Auto Test Equipment (“ATE”), medical, industry applications etc. Such applications desire the trend of high integration or high power density and require power supply or power management apparatus with high power efficiency and lower size such as the power modules/converter modules according to various embodiments of the present disclosure. The composite magnetic material according to various embodiments of the present disclosure with coated magnetic particles (MB) dispersed in the composite non-magnetic material (MA) may meanwhile have improvements in its insulation resistance and/or withstanding voltage, and thus when used as a magnetic molding material, can be directly combined with other components (such as an electrically conductive coil like the electrically conductive coil 13 as described) without a need for complex insulating treatment, which advantageously simplifies the structure and reduces the size and cost of packaged modules including an energy storage device having the electrically conductive coil interacting with the composite magnetic material for example.

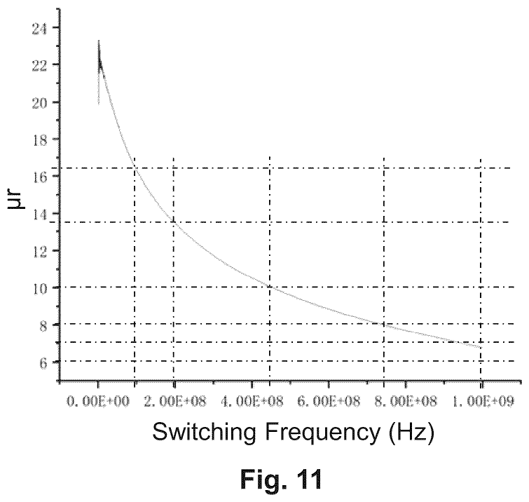

In some embodiments, referring to FIG. 11 which illustrates a waveform diagram illustrating a curve of the relative magnetic permeability ur of some samples of the composite magnetic material versus a switching frequency in accordance with some embodiments of the present disclosure. According to some embodiments, samples of the composite magnetic material have a relative magnetic permeability of no lower than 6.5 at a frequency essentially ranging from 800 MHz to 1000 MHz. According to some embodiments, samples of the composite magnetic material (MA) have a relative magnetic permeability of no lower than 8 at a frequency essentially ranging from 450 MHz to 750 MHz. According to some embodiments, samples of the composite magnetic material (MA) have a relative magnetic permeability of no lower than 10 at a frequency of no greater than 450 MHz. According to some embodiments, samples of the composite magnetic material (MA) have a relative magnetic permeability of no lower than 13 at a frequency of no greater than 200 MHz. According to some embodiments, samples of the composite magnetic material (MA) have a relative magnetic permeability of no lower than 16 at a frequency of no greater than 100 MHz.

In contrast, while conventional molding compounds (such as plastics, epoxy compound etc.) do not exhibit magnetic property, existing magnetic molding compounds cannot provide adequate relative magnetic permeability for applications requiring high energy/power efficiency, low power loss and lower dimensions such as for data center, cloud computing, Artificial Intelligence (“AI”), Auto Test Equipment (“ATE”), medical, industry applications etc. Such applications desire the trend of high integration or high power density and require power supply or power management apparatus with high power efficiency and lower size such as the power modules/converter modules according to various embodiments of the present disclosure. Existing magnetic molding compounds generally feature a relative magnetic permeability that is substantially lower than 10 at a frequency no greater than 200 MHz and have high core loss, and thus even using the existing magnetic molding compounds to mold the winding(s), a magnetic core (e.g., a ferrite core) is needed to be disposed in the winding(s) to form an inductive component with enough inductance, which constrains the enhancement in inductance and reduction in direct current resistance (DCR) of the inductive component especially for meeting the requirements of the aforementioned applications, for example to provide efficient inductive energy storage device for power modules.

In one aspect, the relative magnetic permeability of the existing magnetic molding compounds needs to be increased. In one aspect, the ratios and/or formulations of the resin components need further optimization to improve the performance and properties of the existing magnetic molding compounds. In one aspect, the compositions and/or concentrations or ratios of magnetic metal particle fillers, such as iron (Fe) etc., of the existing magnetic molding compounds, require improvement to achieve better or higher relative magnetic permeability and lower core losses. In one aspect, while enhancing the relative magnetic permeability of the existing magnetic molding compounds, it is desired that other properties of the magnetic molding compounds such as the thermal conductivity, and/or the electrical resistivity, and/or the flowability, and/or the mechanical strength etc. could be improved or at least undegraded. In one aspect, the existing manufacturing processes for magnetic molding compounds and their integration into power module inductors need further refinement to ensure consistent quality, performance, and cost-effectiveness.

In accordance with an exemplary embodiment of the present disclosure, the coated magnetic particles (MB) of the composite magnetic material may each comprise a magnetic metal particle (MB1) and an insulation coating layer (MB2) enclosing or wrapping the magnetic metal particle (MB1). In some embodiments, the insulation coating layer (MB2) contains for example elements Silicon (Si), Carbon (C), and Oxygen (O), etc. In some embodiments, the insulation coating layer (MB2) contains for example elements Silicon (Si), Carbon (C), Oxygen (O), and other elements like Sulfur(S), etc. In some embodiments, the insulation coating layer (MB2) may include a layer of polymer that includes molecules containing for example elements Silicon (Si), Carbon (C), and Oxygen (O), etc. In some embodiments, the insulation coating layer (MB2) may include a layer of polymer that includes molecules containing for example elements Silicon (Si), Carbon (C), Oxygen (O), and other elements like Sulfur(S), etc. Those of ordinary skill in the art would well understand that “element” or “elements” here refers to chemical element/elements. To provide just an example, the insulation coating layer (MB2) may include a layer of polymer that includes silane coupling agents such as γ-Aminopropyl triethoxysilane (KH550) having a chemical structure including a structural unit represented by the general formula (1), γ-(2,3-epoxypropoxy) propytrimethoxysilane (KH560) having a chemical structure including a structural unit represented by the general formula (2), γ-Methacryloxypropyl trimethoxysilane (KH570) having a chemical structure including a structural unit represented by the general formula (3), or dopamine (DA) having a chemical structure including a structural unit represented by the general formula (4), etc., just naming a few examples. In some embodiments, the insulation coating layer (MB2) may include only one type of the silane coupling agents. In some embodiments, the insulation coating layer (MB2) may include two or more types of the silane coupling agents. It can be understood by those of ordinary skill in the art that many known compounds can be used as the insulation coating layer (MB2) without particular limitation as long as the effects of the present invention can be exhibited.

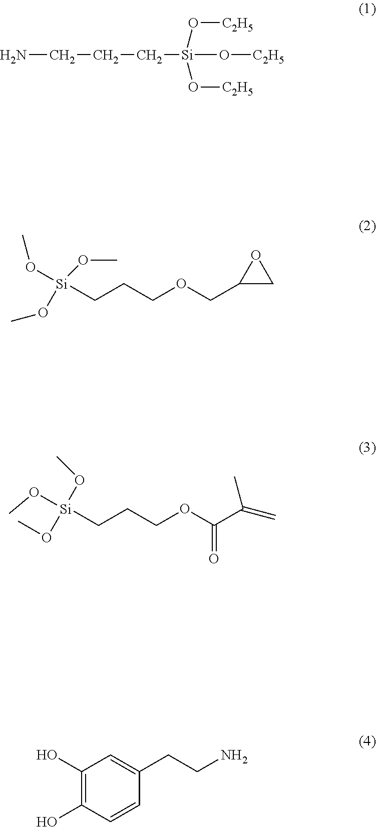 [SMILES: CCO[Si](CCCN)(OCC)OCC ; CO[Si](CCCOCC1CO1)(OC)OC ; C=C(C)C(=O)OCCC[Si](OC)(OC)OC ; NCCc1ccc(O)c(O)c1]

The insulation coating layer (MB2) may in one aspect advantageously help to eliminate or at least reduce aggregation of the coated magnetic particles (MB) and enhance uniformity of dispersion of the coated magnetic particles (MB) within the composite non-magnetic material (MA), which is beneficial to improving the relative magnetic permeability and the electrical resistivity of the composite magnetic material. The insulation coating layer (MB2) containing Si, C, and O, etc. may in one aspect further help to connect the magnetic filler by hydrogen bondings (e.g., bondings between H and O) with the composite non-magnetic material (MA) to facilitate heat transport, which is beneficial to improving a thermal conductivity of the composite magnetic material.

In accordance with some embodiments, the composite magnetic material may comprise the insulation coating layer (MB2) of the coated magnetic particles (MB) in an amount of essentially 0.08% to 3.2% by mass (or weight percentage) based on the composite magnetic material. In accordance with some embodiments, the insulation coating layer (MB2) of the coated magnetic particles (MB) may contain the element Silicon (Si) in an amount of 0.52% to 2.93% by mass (or weight percentage) based on the composite magnetic material with a predetermined tolerance margin of ±20%. In other words, the amount of Silicon (Si) contained in molecules of the insulation coating layer (MB2) of the coated magnetic particles (MB) may be 0.52%×(1±20%) to 2.93%×(1±20%) by mass (or weight percentage) based on the composite magnetic material. In accordance with some embodiments, the insulation coating layer (MB2) of the coated magnetic particles (MB) may contain the element Silicon (Si) in an amount of 0.63% to 1.82% by mass (or weight percentage) based on the composite magnetic material with a predetermined tolerance margin of ±20%. In other words, the amount of Silicon (Si) contained in molecules of the insulation coating layer (MB2) of the coated magnetic particles (MB) may be 0.63%×(1±20%) to 1.82%×(1±20%) by mass (or weight percentage) based on the composite magnetic material. In accordance with some embodiments, the insulation coating layer (MB2) may have a thickness of no greater than 1 μm. In accordance with some embodiments, the insulation coating layer (MB2) may have a thickness of no greater than 200 nm.

In an embodiment, the composite magnetic material comprises the coated magnetic particles (MB) in an amount of substantially 68.3% to 99% by mass (or weight percentage) based on the composite magnetic material. In an embodiment, each magnetic metal particle (MB1) may include iron (Fe), silicon (Si), and/or other elements like aluminum (Al), etc. In an embodiment, the coated magnetic particles (MB) may include Fe at least of 48% by mass (or weight percentage) based on the coated magnetic particles (MB). In an example, the coated magnetic metal particles (MB) include Fe of 48.6% to 90.7% by mass based on the coated magnetic particles (MB). In an embodiment, the magnetic metal particles (MB1) may include Fe at least of 48% by mass (or weight percentage) based on the magnetic metal particles (MB1). In an example, the magnetic metal particles (MB1) may include Fe of 48.6% to 90.7% by mass (or weight percentage) based on the magnetic metal particles (MB1).

In an embodiment, the coated magnetic particles (MB) may have non-uniform sizes and/or may have non-uniform or non-identical (i.e., various) shapes to reduce the viscosity and improve the relative magnetic permeability of the composite magnetic material. In an embodiment, the coated magnetic particles (MB) may be of sphere particles, elliptical particles, or other morphology particles without sharp corners. In an embodiment, the coated magnetic particles (MB) may have sizes (e.g., in median diameters) ranging from 0.3 μm to 54.8 μm. In an embodiment, the coated magnetic particles (MB) may have sizes (e.g., in median diameters) ranging from 0.8 μm to 51.8 μm.

In an embodiment, the coated magnetic particles (MB) or the magnetic filler may include large sized particles having sizes (e.g., in median diameters) essentially ranging from 33.6 μm to 54.8 μm or in an example ranging from 33.6 μm to 51.8 μm. In an embodiment, the coated magnetic particles (MB) or the magnetic filler may further include small sized particles having sizes (e.g., in median diameters) essentially ranging from 0.3 μm to 8.6 μm or in an example ranging from 0.8 μm to 8.6 μm, and/or medium sized particles having sizes (e.g., in median diameters) essentially ranging from 8.7 μm to 33.4 μm.

In an embodiment, the coated magnetic particles (MB) may include the large sized particles in an amount of no lower than 48.6% by mass (or weight percentage) or in an amount of substantially from 48.6% to 79.3% by mass (or weight percentage) based on the coated magnetic particles (MB). In an embodiment, the coated magnetic particles (MB) may include the small sized particles in an amount of no greater than 28.7% by mass (or weight percentage) or in an amount of substantially from 7.2% to 28.7% by mass (or weight percentage) based on the coated magnetic particles (MB). In an embodiment, the coated magnetic particles (MB) may include the medium sized particles in an amount of no greater than 38.4% by mass (or weight percentage) or in an amount of substantially from 11.3% to 38.4% by mass (or weight percentage) based on the coated magnetic particles (MB).

In an embodiment, the coated magnetic particles (MB) may include the large sized particles (e.g., with median diameters essentially of 33.6 μm to 54.8 μm or of 33.6 μm to 51.8 μm) in an amount of no lower than 33.8%×(1±20%) by quantity percentage or in an amount of 33.8% to 76.3% by quantity percentage with a predetermined tolerance margin of +20% based on quantity of the coated magnetic particles (MB), for example when inspected from a cross-sectional view of the composite magnetic material in molded form. In other words, the amount in quantity of large sized particles contained in the coated magnetic particles (MB) may be of no lower than 33.8%× (1±20%) or may be of 33.8%× (1±20%) to 76.3%× (1±20%) by quantity percentage based on quantity of the coated magnetic particles (MB), for example when inspected from a cross-sectional view of the composite magnetic material in molded form.

In an embodiment, the coated magnetic particles (MB) may include the large sized particles (e.g., with median diameters essentially of 33.6 μm to 54.8 μm or of 33.6 μm to 51.8 μm) in an amount of no lower than 48.6% by cross-sectional area percentage or in an amount of substantially from 48.6% to 79.3% by cross-sectional area percentage based on an overall cross-sectional area of the coated magnetic particles (MB), for example when inspected from a cross-sectional view of the composite magnetic material in molded form.

In an embodiment, the coated magnetic particles (MB) may include the small sized particles (e.g., with median diameters essentially of 0.3 μm to 8.6 μm or of 0.8 μm to 8.6 μm) and the medium sized particles (e.g., with median diameters essentially of 8.7 μm to 33.4 μm) in an amount of 22.3% to 62.2% by quantity percentage with a predetermined tolerance margin of +20% based on quantity of the coated magnetic particles (MB), for example when inspected from a cross-sectional view of the composite magnetic material in molded form. In other words, the amount in quantity of the small sized particles and the medium sized particles contained in the coated magnetic particles (MB) may be of 22.3%× (1±20%) to 62.2%× (1±20%) by quantity percentage based on quantity of the coated magnetic particles (MB), for example when inspected from a cross-sectional view of the composite magnetic material in molded form.

In an embodiment, the coated magnetic particles (MB) may include the small sized particles (e.g., with median diameters essentially of 0.3 μm to 8.6 μm or of 0.8 μm to 8.6 μm) in an amount of no greater than 34.6% by quantity percentage based on quantity of the coated magnetic particles (MB), for example when inspected from a cross-sectional view of the composite magnetic material in molded form. In an embodiment, the coated magnetic particles (MB) may include the medium sized particles (e.g., with median diameters essentially of 8.7 μm to 33.4 μm) in an amount of no greater than 34.6% by quantity percentage based on quantity of the coated magnetic particles (MB), for example when inspected from a cross-sectional view of the composite magnetic material in molded form.

In an embodiment, the coated magnetic particles (MB) may include the small sized particles (e.g., with median diameters essentially of 0.3 μm to 8.6 μm or of 0.8 μm to 8.6 μm) in an amount of no greater than 28.7% or in an amount of substantially from 7.2% to 28.7% by cross-sectional area percentage based on an overall cross-sectional area of the coated magnetic particles (MB), for example when inspected from a cross-sectional view of the composite magnetic material in molded form.

In an embodiment, the coated magnetic particles (MB) may include the medium sized particles (e.g., with median diameters essentially of 8.7 μm to 33.4 μm) in an amount of no greater than 38.4% by cross-sectional area percentage or in an amount of substantially from 11.3% to 38.4% by cross-sectional area percentage based on an overall cross-sectional area of the coated magnetic particles (MB), for example when inspected from a cross-sectional view of the composite magnetic material in molded form.

In an embodiment, the coated magnetic particles (MB) may include particles with median diameters no greater than 20 μm in an amount of no greater than 40.8% by mass or by weight percentage based on the coated magnetic particles (MB), or no greater than 47.2% by quantity percentage or no greater than 40.8% by cross-sectional area percentage based on the coated magnetic particles (MB), for example when inspected from a cross-sectional view of the composite magnetic material.

By using the coated magnetic particles (MB) in multiple size ranges (i.e., large sized, and/or small sized, and/or medium sized) and delicately designing and/or adjusting the amount of the small sized particles, and/or the amount of the medium sized particles, and/or the amount of the large sized particles according to embodiments of the present disclosure, it is helpful to improve the composite magnetic material to achieve higher relative magnetic permeability, and meanwhile to achieve improvements in other characteristics or performances such as the flowability and/or the thermal conductivity, or at least without degrading or sacrificing other characteristics or performances such as the flowability and/or the thermal conductivity of the composite magnetic material. For instance, the composite magnetic material according to some embodiments of the present disclosure has a thermal conductivity ranging from 1.6 W/m·K to 4 W/m·K while featuring a sufficiently high relative magnetic permeability for example of no lower than 16 at a frequency of no greater than 100 MHz.

In one aspect, for example, by designing the coated magnetic particles (MB) to include the large sized particles with median diameters essentially of 33.6 μm to 54.8 μm (or alternatively of 33.6 μm to 51.8 μm) in majority, e.g., in an amount of no lower than 33.8%×(1±20%) (or alternatively no lower than 37.8%×(1±20%)) by quantity percentage or no lower than 48.6% by mass or by cross-sectional area percentage based on the coated magnetic particles (MB), the relative magnetic permeability of the composite magnetic material can be improved without degrading the flowability. In contrast, using coated magnetic particles (MB) with median diameters greater than 55 μm in majority may harm the flowability of the composite magnetic material while using coated magnetic particles (MB) with median diameters no greater than 20 μm in an amount of greater than 40.8% by mass or by cross-sectional area percentage or greater than 47.2% by quantity percentage may harm the relative magnetic permeability and thermal conductivity of the composite magnetic material.

In another aspect, for example, by delicately designing and/or tuning the amount of the large sized particles with median diameters essentially of 33.6 μm to 54.8 μm (or alternatively of 33.6 μm to 51.8 μm) contained in the coated magnetic particles (MB) as described with various embodiments above can help to further reduce the overall interfaces between the coated magnetic particles (MB) and the composite non-magnetic material (MA), which is beneficial to improving the relative magnetic permeability and/or thermal conductivity of the composite magnetic material.

In still another aspect, in an embodiment for example, with the coated magnetic particles (MB) designed to include the small sized particles (e.g., with median diameters essentially of 0.3 μm to 8.6 μm or of 0.8 μm to 8.6 μm) or medium sized particles (e.g., with median diameters essentially of 8.7 μm to 33.4 μm) or particles with median diameters of no greater than 20 μm in an amount of no greater than the respective values as described above yet no lower than 10% by quantity percentage or by mass or by cross-sectional area percentage based on the coated magnetic particles (MB), it is helpful to reduce the viscosity, which is beneficial to improving the flowability without degrading the thermal conductivity and/or the relative magnetic permeability of the composite magnetic material.

In accordance with an exemplary embodiment, the composite non-magnetic material (MA) or the non-magnetic polymer matrix (MA) may include a thermoset cross-linkable polymeric resin (MA1) in either its cured or uncured form. In some embodiments, samples of the composite non-magnetic material (MA) or the non-magnetic polymer matrix (MA) may include the thermoset cross-linkable polymeric resin (MA1) in its uncured form and polymer curing agents (MA2). In some embodiments, samples of the composite non-magnetic material (MA) or the non-magnetic polymer matrix (MA) may include the thermoset cross-linkable polymeric resin (MA1) in cured form that has been cured by the polymer curing agents (MA2).

In accordance with an exemplary embodiment, the thermoset cross-linkable polymeric resin (MA1) may include (A11) a resin of epoxy functional groups and (A12) a resin of different functional groups or units that are different from the epoxy functional groups. The resin of epoxy functional groups may have a chemical structure including a structural unit represented by the general formula (5).

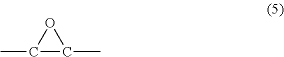

In an embodiment, the resin of epoxy functional groups (A11) may include bisphenol-type epoxy resins, such as a bisphenol A type resin that may have a chemical structure including a structural unit represented by the general formula (6), a bisphenol F type resin that may have a chemical structure including a structural unit represented by the general formula (7), or a biphenyl-type epoxy resin etc., just naming a few examples. In an embodiment, the resin of epoxy functional groups (A11) may include only one type of the epoxy resin or may include two or more types of the epoxy resins. It can be understood by those of ordinary skill in the art that many known compounds can be used as the resin of epoxy functional groups (A11) without particular limitation as long as the effects of the present invention can be exhibited.

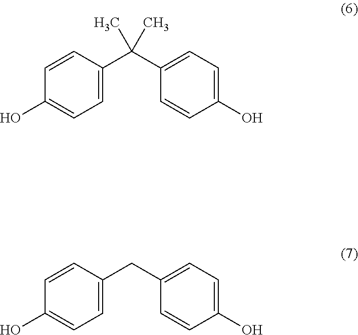 [SMILES: CC(C)(c1ccc(O)cc1)c1ccc(O)cc1 ; Oc1ccc(Cc2ccc(O)cc2)cc1]

In an embodiment, the resin of different functional groups or units (A12) may include one or more compound(s) selected from naphthalene, dicyclopentadiene, amino triazine, and ester, etc. For example, in some embodiments, the naphthalene may have a chemical structure including a structural unit represented by the general formula (8). In some embodiments, the dicyclopentadiene may have a chemical structure including a structural unit represented by the general formula (9). In some embodiments, the amino triazine may have a chemical structure including a structural unit represented by the general formula (10). In some embodiments, the ester may have a chemical structure including a structural unit represented by the general formula (11).

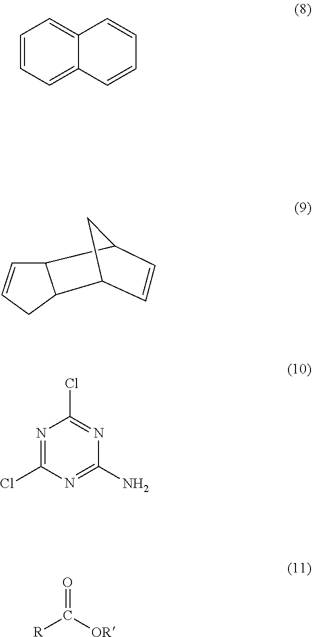

In accordance with an exemplary embodiment, the polymer curing agents (MA2) may include phenol, cresol, or amine groups. The polymer curing agents (MA2) can help to open epoxy rings to facilitate the crosslink between the thermoset cross-linkable polymeric resin (MA1) and the polymer curing agents (MA2).

In an embodiment, a ratio by mass (or by weight) of the thermoset cross-linkable polymeric resin (MA1) and the polymer curing agents (MA2) based on the composite magnetic material may be set essentially between 0.99 and 3.72. With the proper tuning of the ratio by mass of the thermoset cross-linkable polymeric resin (MA1) and the polymer curing agents (MA2) according to embodiments of the present disclosure, improved cross-link network can be formed between the thermoset cross-linkable polymeric resin (MA1) and the polymer curing agents (MA2), which could be beneficial to enhancing the mechanical strength, and/or thermal stability, and/or Coefficient of Thermal Expansion (“CTE”) of the overall composite non-magnetic material (MA), or alternatively speaking of the non-magnetic polymer matrix (MA).

In accordance with an exemplary embodiment, the composite non-magnetic material (MA) or the non-magnetic polymer matrix (MA) in an embodiment may further include other additives (MA3). For instance, other additives selected from one or more of the materials such as catalysts, coupling agents, flame retardants, releasing agents may be added depending on application requirements to certain additional characteristic(s) of the composite non-magnetic material (MA) with which the composite non-magnetic material (MA) is desired to feature. To provide an example, other additives like the catalysts may be added to help to accelerate the reaction between the thermoset cross-linkable polymeric resin (MA1) and the polymer curing agents (MA2). In an embodiment, one or more catalyst(s) may be selected from imidazole, phosphate and Metal Ionics and added as an additive to the composite non-magnetic material (MA). The composite non-magnetic material (MA) or the non-magnetic polymer matrix (MA) is silicon dioxide free.

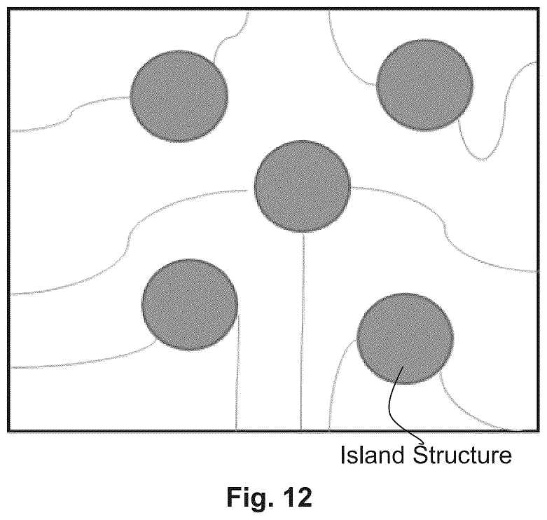

In accordance with an exemplary embodiment, the composite magnetic material may further include a modulus reducing filler (MC) including modulus reducing particles. The modulus reducing filler (MC) or the modulus reducing particles may be embedded or dispersed within the composite non-magnetic material (MA), for example in a substantially uniform manner. The modulus reducing filler (MC) or the modulus reducing particles in an embodiment may include functional groups having —OH or —COOH. In some embodiments, the modulus reducing filler (MC) or the modulus reducing particles may include rubber particles. For example, the modulus reducing particles or the rubber particles may include functional groups having —OH or —COOH. The modulus reducing filler (MC) can react with the resin of epoxy functional groups (A11) of the thermoset cross-linkable polymeric resin (MA1) to form connections or links between the modulus reducing particles (MC) and the composite non-magnetic material (MA), for example between the modulus reducing particles (MC) and the resin of epoxy functional groups (A11). The modulus reducing particles may form island structures within the composite non-magnetic material (MA) as illustratively shown in FIG. 12 which illustratively shows a portion of the composite magnetic material including the island structures within the composite non-magnetic material (MA). Therefore, the modulus reducing filler (MC) can help to reduce the modulus of the composite magnetic material while maintain a sufficient mechanical strength of the composite magnetic material, which is beneficial to eliminating or at least reducing the possibility of cracks or delamination during a molding process when the composite magnetic material is used as a molding material or a molding compound or molding encapsulant for example for manufacturing or forming components such as the packaged modules in accordance with various embodiments of the present disclosure and/or inductive components in accordance with various embodiments of the present disclosure.

In an embodiment, the composite magnetic material comprises the modulus reducing filler (MC) or modulus reducing particles (MC) in an amount of substantially 0.8% to 17.3% by mass (or weight percentage) based on the composite magnetic material. In an example, the composite magnetic material comprises the modulus reducing filler (MC) or modulus reducing particles (MC) in an amount of substantially 0.8% to 15.3% by mass (or weight percentage) based on the composite magnetic material.

With the magnetic filler (e.g., the coated magnetic particles) MB and the modulus reducing filler (e.g., the modulus reducing particles) MC, the composite magnetic material in accordance with various embodiments of the present disclosure may feature a high relative magnetic permeability with a comparable low modulus performance and an improved flowability over common or existing molding compounds (either conventional non-magnetic or magnetic).

As used in the present disclosure, the term “non-magnetic polymer matrix” refers to the composite non-magnetic material (MA) of the composite magnetic material in either its cured or uncured form. As used herein, “resin” or the “thermoset cross-linkable polymeric resin (MA1)” may be in its cured or uncured form. In the cases when polymer curing agents (MA2) are needed to induce the curing of the resin (e.g., the thermoset cross-linkable polymeric resin), the term “resin” refers to the main component of the non-magnetic polymer matrix excluding the polymer curing agents (MA2). In other words, the term “non-magnetic polymer matrix” refers to the composite non-magnetic material (MA) including the thermoset cross-linkable polymeric resin (MA1) in either its cured or uncured form. The polymer curing agents (MA2) can be added to the thermoset cross-linkable polymeric resin (MA1) before or after the addition of magnetic fillers (MB) and/or other additives (MA3) and/or modulus reducing fillers (MC).

In accordance with an embodiment of the present disclosure, the composite magnetic material as described with reference to the exemplary embodiments may be used to implement the MMC 14 as mentioned or described according to various embodiments of the present disclosure. For instance, the packaged modules of various embodiments as described with reference to FIG. 2A to FIG. 8K can include the MMC 14 that may be implemented with the composite magnetic material as described according to various embodiments of the present disclosure.

For another instance, in the exemplary embodiment of a method for manufacturing a packaged module for power conversion as described with reference to FIG. 9 or FIG. 10, the MMC 14 may be implemented with the composite magnetic material as described according to various embodiments of the present disclosure. For this situation, it can be easily understood by persons of ordinary skill in the art that substantial descriptions made to the method for manufacturing a packaged module with reference to FIG. 9 or FIG. 10 would still apply when using the composite magnetic material as described according to various embodiments to implement the MMC 14. Following are just some explanations to some steps to help with a better understanding. Without these explanations, those of ordinary skill in the art would still be able to well understand the method for manufacturing a packaged module with reference to FIG. 9 or FIG. 10 when using the composite magnetic material as described according to various embodiments to implement the MMC 14.

At step 906 or 1006, a process of magnetic particles treatment may be executed. In this process, the magnetic metal particles 143 can be implemented with the magnetic metal particles (MB1), the insulation coating layer 144 can be implemented with the insulation coating layer (MB2), and accordingly the coated magnetic particles 142 formed would include the coated magnetic particles (MB) for this example. In an embodiment, the process of magnetic particles treatment may include a coating process to coat and encapsulate each one of the magnetic metal particles (MB1) with a coating layer of the insulation coating layer (MB2) to form the coated magnetic particles (MB). The coating process in an embodiment may use for example a polymer that includes elements Si, C, and O, etc. for surface treatment to the magnetic metal particles (MB1) to form the insulation coating layer (MB2) coating each one of the magnetic metal particles (MB1). The coating process in an embodiment may use for example a polymer that includes silane coupling agents for surface treatment to the magnetic metal particles (MB1) to form the insulation coating layer (MB2) coating each one of the magnetic metal particles (MB1). More details of the insulation coating layer (MB2) formed in the process of magnetic particles treatment can be understood with reference to related descriptions made above in connection with the composite magnetic material and will not need to be addressed here again.

At step 907 or 1007, an ingredient treatment process may be performed. For example, ingredients of the composite magnetic material that is suitable to implement or to be used as the MMC 14 may be mixed to form a mixture of magnetic materials. The ingredients may include the composite non-magnetic material (MA) which could be used as the non-magnetic material 141 and the coated magnetic particles (MB) which could be used as the coated magnetic particles 142 in an exemplary embodiment. The ingredients may further include the modulus reducing fillers (MC) in an exemplary embodiment. In this process, the coated magnetic particles (MB) or 142 may be dispersed throughout the composite non-magnetic material (MA) or the non-magnetic material 141. The mixture of magnetic materials may be in fluid or gelatinous status. In other words, a composite magnetic material in fluid or gelatinous form may be obtained after the ingredient treatment process of 907 or 1007.

At step 909, the dried mixture of magnetic materials may be pulverized. After the pulverization process, a composite magnetic material in powder form may be obtained. The powder composite magnetic material may be used as a powder magnetic molding compound (“MMC”) 14 that is compatible with a molding process such as a compression molding process, etc.

In an embodiment, a step 910 may optionally be further performed after the step 909. At step 910, a pelleting process can be performed so that the composite magnetic material in powder form may further be pelleted (e.g., granularly shaped such as in small or tiny cylinder shape or sphere shape or elliptical shape etc.) to form a composite magnetic material in pelleted form. The pelleted composite magnetic material obtained after the pelleting process may be used as a pelleted magnetic molding compound (“MMC”) 14 that is compatible with a molding process such as a transfer molding process, etc.

At step 911, a molding process may be performed using the composite magnetic material as a molding material (e.g., to implement the magnetic molding compound 14), for example, to encapsulate or cover components needing to be molded such as those components (e.g., the electrically conductive coil(s) 13, and/or the power switching unit 12, and/or other components) that are attached/mounted on the substrate panel in some embodiments. The composite magnetic material is adapted to directly replace a conventional molding compound in the molding process. For instance, the powder composite magnetic material obtained after step 909 is adapted to be used as the magnetic molding compound 14 and directly replace a conventional molding compound in a compression molding process. The pelleted composite magnetic material obtained after step 910 is adapted to be used as the magnetic molding compound 14 and directly replace a conventional molding compound in a transfer molding process.

In some embodiments, after the ingredient treatment process of 1007, the mixture of magnetic materials in fluid or gelatinous status or the composite magnetic material in fluid or gelatinous form may be adapted to implement or be used as a fluid or gelatinous magnetic molding compound (“MMC”) 14 that is compatible with a molding process such as a gel-casting molding process, etc. Accordingly, at step 1009, a molding process such as a gel-casting molding process may be performed to fill or perfuse the mixture of magnetic materials in fluid or gelatinous status so that the composite magnetic material in fluid or gelatinous form is used as the magnetic molding compound 14 and filled in the packaged modules in accordance with various embodiments of the present invention.

One of ordinary skill in the art would understand that the molding process or molding method is definitely not limited to the examples given here. One of ordinary skill in the art would also understand that for embodiments with the inductive energy storage device embedded in the substrate 11, the molding process may alternatively be performed at the step 901 or 1001 during preparing the substrate panel.

In accordance with some embodiments, the composite magnetic material as described according to various embodiments may be used to manufacture or form inductive components including but not limited to discrete inductive components or integrated inductive components. For example, integrated inductive components like the inductive energy storage device 120 that includes the electrically conductive coil 13 and the MMC 14 as described with various embodiments of the present disclosure may be formed with the MMC 14 implemented with the composite magnetic material. For another example, discrete inductive components like molded inductor or molded transformer including conductive coil(s) encapsulated or molded with the composite magnetic material may be formed. Those of ordinary skill in the art would understand that examples here are not intended to be limiting. The composite magnetic material according to various embodiments of the present disclosure could be used to manufacture any other components where magnetism is requisite, requiring the properties or performance of the composite magnetic material as described.

In the manufacture of electronic devices, apparatus, components etc. according to some embodiments of the present disclosure, the composite magnetic material can be used as a molding material, such as a powder molding material that is adapted for or compatible with a compression molding process, or a pelleted molding material that is adapted for or compatible with a transfer molding process or a paste or gelatinous molding material that is adapted for or compatible with a gel-casting molding process.

In some embodiments, a method for forming a magnetic molding material (in fluid or gelatinous form for example) may comprise providing or forming a magnetic filler including coated magnetic particles (MB), for example, including the step 906 or step 1006 as described with reference to FIG. 9 or FIG. 10 in related paragraphs above and will not need to be repeated here again. The method for forming the magnetic molding material (in gelatinous form for example) may further comprise forming a composite magnetic material in fluid or gelatinous form by an ingredient treatment process to mix ingredients of the composite magnetic material, for example, including the step 907 or step 1007 as described with reference to FIG. 9 or FIG. 10 in related paragraphs above and will not need to be repeated here again.

In some embodiments, a molding method using the composite magnetic material as described with various embodiments of the present disclosure may comprise: providing or forming a magnetic molding material (in gelatinous form for example) that may be obtained by the method for forming the magnetic molding material as described here; and performing a molding process using the composite magnetic material (in gelatinous form for example) as a molding material, for example including the step 1009 as described with reference to FIG. 10 in related paragraphs above and will not need to be repeated here again. A vacuuming process such as described with the step 1008 may be executed before the molding process.

In some embodiments, a method for forming a magnetic molding material (in powder form for example) may comprise: providing or forming a magnetic filler including coated magnetic particles (MB), for example including the step 906; forming a composite magnetic material (in fluid or gelatinous form for example) by an ingredient treatment process, for example including the step 907; a drying process for example as described with the step 908; and a pulverization process to form a composite magnetic material in powder form, for example including the step 909; as described with reference to FIG. 9 in related paragraphs above and will not need to be repeated here again.

In some embodiments, a molding method using the composite magnetic material as described with various embodiments of the present disclosure may comprise: providing or forming a magnetic molding material (in powder form for example) that may be obtained by the method for forming the magnetic molding material as described here; and performing a molding process using the composite magnetic material (in powder form for example) as a molding material, for example including the step 911 as described with reference to FIG. 9 in related paragraphs above and will not need to be repeated here again.

In some embodiments, a method for forming a magnetic molding material (in pelleted form for example) may comprise: providing or forming a magnetic filler including coated magnetic particles (MB), for example including the step 906; forming a composite magnetic material (in fluid or gelatinous form for example) by an ingredient treatment process, for example including the step 907; a drying process for example as described with the step 908; a pulverization process to form a composite magnetic material in powder form, for example, including the step 909; and a pelleting process to convert the composite magnetic material in powder form to a composite magnetic material in pelleted form, for example, including the step 910; as described with reference to FIG. 9 in related paragraphs above and will not need to be repeated here again.

In some embodiments, a molding method using the composite magnetic material as described with various embodiments of the present disclosure may comprise: providing or forming a magnetic molding material (in pelleted form for example) that may be obtained by the method for forming the magnetic molding material as described here; and performing a molding process using the composite magnetic material (in pelleted form for example) as a molding material, for example including the step 911 as described with reference to FIG. 9 in related paragraphs above and will not need to be repeated here again.

The advantages of the various embodiments of the present invention are not confined to those described above. These and other advantages of the various embodiments of the present invention will become more apparent upon reading the whole detailed descriptions and studying the various figures of the drawings.

From the foregoing, it will be appreciated that specific embodiments of the present invention have been described herein for purposes of illustration, but that various modifications may be made without deviating from the technology. Many of the elements of one embodiment may be combined with other embodiments in addition to or in lieu of the elements of the other embodiments.

What is claimed is:

1. A packaged module, comprising:
an electrically conductive coil; and
a composite magnetic molding material covering the electrically conductive coil, wherein the composite magnetic molding material includes a magnetic filler including coated magnetic particles (MB) dispersed in a composite non-magnetic material (MA) and a modulus reducing filler (MC) including modulus reducing particles or rubber particles or including functional groups having —OH or —COOH.

2. The packaged module of claim 1, further comprising:
a substrate having a first surface and a second surface opposite to the first surface, wherein the second surface has a plurality of pins, and wherein the electrically conductive coil is disposed on the first surface of the substrate.

3. The packaged module of claim 2, wherein the substrate includes a plurality of electrically conductive wiring structures configured to provide interconnections or electrical couplings between the electrically conductive coil and one or more of the plurality of pins.

4. The packaged module of claim 2, wherein the electrically conductive coil has coil terminals configured to be substantially coplanar with each other and directly attached to corresponding pads on the first surface of the substrate.

5. The packaged module of claim 1, further comprising:
an integrated circuit (“IC”) die disposed in the packaged module and being configured to co-work with an integrated inductive energy storage device including the electrically conductive coil and the composite magnetic molding material.

6. The packaged module of claim 1, wherein the electrically conductive coil is core-less.

7. The packaged module of claim 1, wherein the electrically conductive coil is conformally coated with a thin insulation layer and has coil terminals with each one of the coil terminals having an exposed area that is free of coverage from the thin insulation layer.

8. The packaged module of claim 1, wherein the electrically conductive coil is configured to have a winding having multiple wiring turns wound along a predetermined direction in a helix-like shape.

9. The packaged module of claim 1, wherein the electrically conductive coil is configured to have a winding having a single turn in the form of a conductive spread sheet wound along a predetermined direction.

10. The packaged module of claim 1, wherein the composite magnetic molding material includes the coated magnetic particles (MB) in an amount of 68.3% to 99% by mass.

11. The packaged module of claim 1, wherein an amount of the modulus reducing filler (MC) in the composite magnetic material is in a range of substantially 0.8% to 17.3% by mass.

12. The packaged module of claim 1, wherein the coated magnetic particles include magnetic metal particles (MB1) that are surface coated with an insulation coating layer (MB2).

13. The packaged module of claim 1, wherein the coated magnetic particles (MB) include iron (Fe) and silicon (Si) or includes Fe of 48.6% to 90.7% by mass.

14. The packaged module of claim 1, wherein the coated magnetic particles have non-uniform sizes and/or non-uniform shapes or have sizes in median diameters ranging from 0.3 μm to 54.8 μm.

15. The packaged module of claim 1, wherein the coated magnetic particles (MB) include large sized particles having sizes in median diameters essentially ranging from 33.6 μm to 54.8 μm, and/or small sized particles with median diameters essentially ranging from 0.3 μm to 8.6 μm and/or medium sized particles having sizes in median diameters essentially ranging from 8.7 μm to 33.4 μm.

16. The packaged module of claim 1, wherein the coated magnetic particles (MB) include large sized particles with median diameters essentially ranging from 33.6 μm to 54.8 μm in an amount of no lower than 33.8%×(1±20%) by quantity percentage or in an amount of 33.8% to 76.3% by quantity percentage with a predetermined tolerance margin of ±20%, or in an amount of no lower than 48.6% by cross-sectional area percentage or in an amount of substantially from 48.6% to 79.3% by cross-sectional area percentage, or in an amount of no lower than 48.6% by mass or in an amount of substantially from 48.6% to 79.3% by mass.

17. The packaged module of claim 1, wherein the coated magnetic particles (MB) include particles with median diameters no greater than 20 μm in an amount of no greater than 40.8% by mass or by cross-sectional area percentage, or no greater than 47.2% by quantity percentage.

18. The packaged module of claim 1, wherein the coated magnetic particles (MB) include small sized particles with median diameters essentially ranging from 0.3 μm to 8.6 μm in an amount of no greater than 34.6% by quantity percentage, or in an amount of no greater than 28.7% by cross-sectional area percentage or in an amount of substantially from 7.2% to 28.7% by cross-sectional area percentage, or in an amount of no greater than 28.7% by mass or in an amount of substantially from 7.2% to 28.7% by mass.

19. The packaged module of claim 1, wherein the coated magnetic particles (MB) include medium sized particles with median diameters essentially ranging from 8.7 μm to 33.4 μm in an amount of no greater than 34.6% by quantity percentage, or in an amount of no greater than 38.4% by cross-sectional area percentage or in an amount of substantially from 11.3% to 38.4% by cross-sectional area percentage, or in an amount of no greater than 38.4% by mass or in an amount of substantially from 11.3% to 38.4% by mass.

20. The packaged module of claim 1, wherein, the coated magnetic particles (MB) include small sized particles with median diameters essentially ranging from 0.3 μm to 8.6 μm and medium sized particles with median diameters essentially ranging from 8.7 μm to 33.4 μm in an amount of 22.3% to 62.2% by quantity percentage with a predetermined tolerance margin of +20%.

21. The packaged module of claim 1, wherein the coated magnetic particles (MB) are surface coated with an insulation coating layer (MB2) that contains elements Silicon (Si), Carbon (C), and Oxygen (O).

22. The packaged module of claim 1, wherein the coated magnetic particles are surface coated with an insulation coating layer (MB2) that contains element Si in an amount of 0.52% to 2.93% of the composite magnetic material by mass with a predetermined tolerance margin of +20%.

23. The packaged module of claim 1, wherein the coated magnetic particles are surface coated with an insulation coating layer (MB2) that includes a layer of polymer including silane coupling agents or that includes one or more types of silane coupling agents selected from KH550, KH560, KH570 and DA.

24. The packaged module of claim 1, wherein the composite non-magnetic material (MA) includes a thermoset cross-linkable polymeric resin (MA1).

25. The packaged module of claim 1, wherein the modulus reducing filler (MC) or the modulus reducing particles or rubber particles form island structures within the composite non-magnetic material (MA).

26. The packaged module of claim 1, wherein the composite magnetic molding material has a relative magnetic permeability of no lower than 6.5 at a frequency essentially ranging from 800 MHz to 1000 MHz, or a relative magnetic permeability of no lower than 8 at a frequency essentially ranging from 450 MHz to 750 MHz, or a relative magnetic permeability of no lower than 10 at a frequency of no greater than 450 MHz, or a relative magnetic permeability of no lower than 13 at a frequency of no greater than 200 MHz, or a relative magnetic permeability of no lower than 16 at a frequency of no greater than 100 MHz.

27. The packaged module of claim 1, wherein the magnetic molding compound has a low core-loss of essentially 15 kW/m³ to 60 KW/m³ at 5 mT and/or a thermal conductivity ranging from 1.6 W/m·K to 4 W/m·K.

28. The packaged module of claim 1, wherein the electrically conductive coil includes a substantial body including wiring turns wound along a direction of a height of the packaged module.

29. The packaged module of claim 28, wherein a top side wiring turn and a bottom side wiring turn of the electrically conductive coil are respectively substantially plan.

30. The packaged module of claim 28, wherein the electrically conductive coil has coil terminals with each one of the coil terminals integrally formed as part of a wiring turn of the electrically conductive coil and is stretched out from the wiring turn to beyond the substantial body in a width and length plane of the packaged module.

31. The packaged module of claim 1, wherein the electrically conductive coil includes wiring turns wound into multiple layers when inspected from a plane view perpendicular to a direction of a height of the packaged module.

32. The packaged module of claim 1, wherein the electrically conductive coil has coil terminals with one or more of the coil terminals vertically bent down to reach a substantially same plane as rest of the coil terminals.

33. The packaged module of claim 28, wherein the packaged module is configured to support an operating current ranging from 1A to 4A with the electrically conductive coil being wound with a round coil wire having a wire diameter no greater than 0.3 mm, or wherein the packaged module is configured to support an operating current ranging from 4A to 10A with the electrically conductive coil being wound with a round coil wire having a wire diameter no greater than 0.4 mm.

34. The packaged module of claim 1, wherein the packaged module is configured to support an operating current ranging from 1A to 4A or from 4A to 10A, and wherein the packaged module has a power conversion efficiency peak value higher than 85% up to or higher than 90%.

35. The packaged module of claim 1, wherein the electrically conductive coil includes wiring turns wound along a direction of a width or a length of the packaged module.

36. The packaged module of claim 35, wherein a substantial body of the electrically conductive coil that includes the wiring turns has a bottom side that is substantially flat.

37. The packaged module of claim 35, wherein the electrically conductive coil has coil terminals with each one of the coil terminals integrally formed as part of a flat portion of a wiring turn of the electrically conductive coil.

38. The packaged module of claim 37, wherein the electrically conductive coil is conformally coated with a thin insulation layer, and wherein each one of the coil terminals has an exposed area that is free of coverage from the thin insulation layer, and wherein for each one of the coil terminals, the exposed area spreads from an end edge of the coil terminal to a position which lands in a scope from a minimum position to a maximum position located on the flat portion that the coil terminal is integrally formed with.

39. The packaged module of claim 1, further comprising:
a substrate; and
an IC die disposed on a first surface of the substrate or embedded inside the substrate; wherein the electrically conductive coil is disposed on the first surface of the substrate or embedded inside the substrate.

40. The packaged module of claim 39, wherein the substrate further has a second surface opposite to the first surface and a plurality of pins formed on the second surface, wherein the plurality of pins include an input pin and a switch pin disposed at a first peripheral side of the packaged module, and wherein the input pin is capable of receiving an input voltage, and wherein the switch pin is electrically coupled to the IC die and the electrically conductive coil.

41. The packaged module of claim 40, wherein the plurality of pins further include output pins disposed at a second peripheral side which is opposite to the first peripheral side of the packaged module.
